(19) United States
(12) Patent Application Publication
(10) Pub. No.: US 2015/0294990 A1
(43) Pub. Date: Oct. 15, 2015

(54) SEMICONDUCTOR DEVICE AND ELECTRONIC DEVICE

(71) Applicant: Semiconductor Energy Laboratory Co., Ltd., Atsugi-shi (JP)

(72) Inventors: Shunpei YAMAZAKI, Tokyo (JP); Tomoaki ATSUMI, Hadano (JP); Yuta ENDO, Atsugi (JP)

(21) Appl. No.: 14/679,104

(22) Filed: Apr. 6, 2015

(30) Foreign Application Priority Data
Apr. 11, 2014 (JP) 2014-081822

(51) Int. Cl. H01L 27/12; H01L 29/04; H01L 29/16; H01L 29/24; H01L 29/786

(52) U.S. Cl. CPC H01L 27/1207; H01L 29/24; H01L 29/7869; H01L 29/16; H01L 29/04; H01L 27/1255

(57) ABSTRACT

A highly integrated semiconductor device is provided. A first region of a first semiconductor and a first region of a second semiconductor overlap each other. A first region of the first conductor and the first region of the first semiconductor overlap each other with a first insulator interposed therebetween. A first region of a second conductor and the first region of the second semiconductor overlap each other with a second insulator interposed therebetween. A first region of a third conductor is in contact with a second region of the first semiconductor. A second region of the third conductor is in contact with a second region of the second semiconductor. A first region of a fourth conductor is in contact with a second region of the first conductor. A second region of the fourth conductor is in contact with a second region of the second conductor.

### TECHNICAL FIELD

The present invention relates to, for example, a transistor, a semiconductor device, and manufacturing methods thereof The present invention relates to, for example, a display device, a light-emitting device, a lighting device, a power storage device, a memory device, a processor, and an electronic device. The present invention relates to a method for manufacturing a display device, a liquid crystal display device, a light-emitting device, a memory device, and an electronic device. The present invention relates to a driving method of a semiconductor device, a display device, a liquid crystal display device, a light-emitting device, a memory device, and an electronic device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

### BACKGROUND ART

In recent years, a transistor including an oxide semiconductor has attracted attention. An oxide semiconductor can be formed by a sputtering method or the like, and thus can be used for a semiconductor of a transistor in a large display device. In addition, the transistor including an oxide semiconductor is advantageous in reducing capital investment because part of production equipment for a transistor including amorphous silicon can be retrofitted and utilized.

It is known that a transistor including an oxide semiconductor has an extremely low leakage current in an off state. For example, a low-power-consumption CPU utilizing a characteristic of low leakage current of the transistor including an oxide semiconductor is disclosed (see Patent Document 1).

### REFERENCE

### Patent Document

[Patent Document 1] Japanese Published Patent Application No. 2012-257187

### DISCLOSURE OF INVENTION

One object is to provide a semiconductor device that occupies a small area. Another object is to provide a highly integrated semiconductor device. Another object is to provide a semiconductor device that operates at high speed. Another object is to provide a semiconductor device with low power consumption. Another object is to provide a semiconductor device with high productivity. Another object is to provide semiconductor devices with high yield. Another object is to provide a novel semiconductor device. Another object is to provide a module including any of the above semiconductor devices. Another object is to provide an electronic device including any of the above semiconductor devices or the module.

Note that the descriptions of these objects do not disturb the existence of other objects. In one embodiment of the present invention, there is no need to achieve all the objects. Other objects will be apparent from and can be derived from the descriptions of the specification, the drawings, the claims, and the like.

(1)

One embodiment of the present invention is a semiconductor device including a first semiconductor, a second semiconductor, a first conductor, a second conductor, a third conductor, a fourth conductor, a first insulator, and a second insulator. A first region of the first semiconductor and a first region of the second semiconductor overlap each other. A first region of the first conductor and the first region of the first semiconductor overlap each other with the first insulator interposed therebetween. A first region of the second conductor and the first region of the second semiconductor overlap each other with the second insulator interposed therebetween. A first region of the third conductor is in contact with a second region of the first semiconductor. A second region of the third conductor is in contact with a second region of the second semiconductor. A first region of the fourth conductor is in contact with a second region of the first conductor. A second region of the fourth conductor is in contact with a second region of the second conductor.

(2)

Another embodiment of the present invention is a semiconductor device including a first semiconductor, a second semiconductor, a first conductor, a second conductor, a third conductor, a fourth conductor, a first insulator, and a second insulator. A first region of the first semiconductor and a first region of the second semiconductor overlap each other. A first region of the first conductor and the first region of the first semiconductor overlap each other with the first insulator interposed therebetween. A first region of the second conductor and the first region of the second semiconductor overlap each other with the second insulator interposed therebetween. A first region of the third conductor is in contact with a second region of the first semiconductor. A second region of the third conductor is in contact with a second region of the second semiconductor. A first region of the fourth conductor is in contact with a third region of the first semiconductor. A second region of the fourth conductor is in contact with a third region of the second semiconductor.

(3)

Another embodiment of the present invention is the semiconductor device according to (1) or (2), in which the first semiconductor contains single crystal silicon.

(4)

Another embodiment of the present invention is the semiconductor device according to any one of (1) to (3), in which the second semiconductor contains an oxide containing indium.

A semiconductor device that occupies a small area can be provided. A highly integrated semiconductor device can be provided. A semiconductor device that operates at high speed can be provided. A semiconductor device with low power consumption can be provided. A semiconductor device with high productivity can be provided. Semiconductor devices can be provided with high yield. A novel semiconductor device can be provided. A module including any of the above semiconductor devices can be provided. An electronic device including any of the above semiconductor devices or the module can be provided.

Note that the descriptions of these effects do not disturb the existence of other effects. One embodiment of the present invention does not necessarily achieve all the above effects. Other effects will be apparent from and can be derived from the descriptions of the specification, the drawings, the claims, and the like.

### BRIEF DESCRIPTION OF DRAWINGS

In the accompanying drawings:

FIG. 1 is a circuit diagram of an inverter circuit of one embodiment of the present invention;

FIGS. 2A and 2B are a top view and a cross-sectional view of an inverter circuit of one embodiment of the present invention;

FIGS. 3A and 3B are a top view and a cross-sectional view of an inverter circuit of one embodiment of the present invention;

FIGS. 4A and 4B are a top view and a cross-sectional view of an inverter circuit of one embodiment of the present invention;

FIGS. 5A and 5B are a top view and a cross-sectional view of an inverter circuit of one embodiment of the present invention;

FIGS. 6A and 6B are a top view and a cross-sectional view of an inverter circuit of one embodiment of the present invention;

FIGS. 7A and 7B are a top view and a cross-sectional view of an inverter circuit of one embodiment of the present invention;

FIGS. 8A and 8B are cross-sectional views each illustrating an inverter circuit of one embodiment of the present invention;

FIGS. 9A and 9B are cross-sectional views each illustrating an inverter circuit of one embodiment of the present invention;

FIG. 10A is a cross-sectional view illustrating a part of a transistor of one embodiment of the present invention, and FIG. 10B shows a band diagram thereof;

FIGS. 11A to 11C are cross-sectional views illustrating a method for manufacturing an inverter circuit of one embodiment of the present invention;

FIGS. 12A to 12C are cross-sectional views illustrating a method for manufacturing an inverter circuit of one embodiment of the present invention;

FIG. 13 is a circuit diagram of an analog switch circuit of one embodiment of the present invention;

FIGS. 14A and 14B are a top view and a cross-sectional view of an analog switch circuit of one embodiment of the present invention;

FIGS. 15A and 15B are circuit diagrams each illustrating a logic circuit of one embodiment of the invention;

FIG. 16 is a block diagram illustrating a CPU of one embodiment of the present invention;

FIG. 17 is a circuit diagram of a memory element of one embodiment of the present invention; FIGS. 18A to 18F illustrate electronic devices of one embodiment of the present invention;

FIGS. 19A to 19D are Cs-corrected high-resolution TEM images of a cross section of a CAAC-OS and a cross-sectional schematic view of a CAAC-OS;

FIGS. 20A to 20D are Cs-corrected high-resolution TEM images of a plane of a CAAC-OS;

FIGS. 21A to 21C show structural analysis of a CAAC-OS and a single crystal oxide semiconductor by XRD;

FIGS. 22A and 22B show electron diffraction patterns of a CAAC-OS; and

FIG. 23 shows a change of crystal parts of an In-Ga-Zn oxide owing to electron irradiation.

### BEST MODE FOR CARRYING OUT THE INVENTION

Hereinafter, embodiments of the present invention will be described in detail with the reference to the drawings. However, the present invention is not limited to the description below, and it is easily understood by those skilled in the art that modes and details disclosed herein can be modified in various ways. Further, the present invention is not construed as being limited to description of the embodiments. In describing structures of the present invention with reference to the drawings, common reference numerals are used for the same portions in different drawings. Note that the same hatched pattern is applied to similar parts, and the similar parts are not especially denoted by reference numerals in some cases.

Note that the size, the thickness of films (layers), or regions in drawings is sometimes exaggerated for clarity.

In this specification, for example, when the shape of an object is described with the use of a term such as “diameter”, “grain size (diameter)”, “dimension”, “size”, or “width”, the term can be regarded as the length of one side of a minimal cube where the object fits, or an equivalent circle diameter of a cross section of the object. The term “equivalent circle diameter of a cross section of the object” refers to the diameter of a perfect circle having the same area as the cross section of the object.

A voltage usually refers to a potential difference between a given potential and a reference potential (e.g., a ground potential (GND) or a source potential). A voltage can be referred to as a potential.

Note that the ordinal numbers such as “first” and “second” in this specification are used for convenience and do not denote the order of steps or the stacking order of layers. Therefore, for example, the term “first” can be replaced with the term “second”, “third”, or the like as appropriate. In addition, the ordinal numbers in this specification and the like are not necessarily the same as those which specify one embodiment of the present invention.

Note that a “semiconductor” includes characteristics of an “insulator” in some cases when the conductivity is sufficiently low, for example. Further, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Further, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor. For example, an element with a concentration lower than 0.1 atomic % is an impurity. When an impurity is contained, the density of states (DOS) may be formed in a semiconductor, the carrier mobility may be decreased, or the crystallinity may be decreased, for example. In the case where the semiconductor is an oxide semiconductor, examples of an impurity which changes characteristics of the semiconductor include Group 1 elements, Group 2 elements, Group 14 elements, Group 15 elements, and transition metals other than the main components; specifically, there are hydrogen (included in water), lithium, sodium, silicon, boron, phosphorus, carbon, and nitrogen, for example. When the semiconductor is an oxide semiconductor, oxygen vacancies may be formed by entry of impurities such as hydrogen, for example. Further, when the semiconductor is a silicon film, examples of an impurity which changes the characteristics of the semiconductor include oxygen, Group 1 elements except hydrogen, Group 2 elements, Group 13 elements, and Group 15 elements.

In this specification, the phrase “A has a region with a concentration B” includes, for example, the cases where “the concentration in the entire region in a region of A in the depth direction is B”, “the average concentration in a region of A in the depth direction is B”, “the median value of the concentration in a region of A in the depth direction is B”, “the maximum value of the concentration in a region of A in the depth direction is B”, “the minimum value of the concentration in a region of A in the depth direction is B”, “a convergence value of the concentration in a region of A in the depth direction is B”, and “a concentration in a region of A in which a probable value is obtained in measurement is B”.

In this specification, the phrase “A has a region with a size B, a length B, a thickness B, a width B, or a distance B” includes, for example, “the size, the length, the thickness, the width, or the distance of the entire region in a region of A is B”, “the average value of the size, the length, the thickness, the width, or the distance of a region of A is B”, “the median value of the size, the length, the thickness, the width, or the distance of a region of A is B”, “the maximum value of the size, the length, the thickness, the width, or the distance of a region of A is B”, “the minimum value of the size, the length, the thickness, the width, or the distance of a region of A is B”, “a convergence value of the size, the length, the thickness, the width, or the distance of a region of A is B”, and “the size, the length, the thickness, the width, or the distance of a region of A in which a probable value is obtained in measurement is B”.

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap each other or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on a transistor structure, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure (also referred to as a 3D structure), an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of the semiconductor in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that the shape of a semiconductor is known. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap each other is referred to as a surrounded channel width (SCW) in some cases. Furthermore, in this specification, in the case where the term “channel width” is simply used, it may denote a surrounded channel width or an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, a value different from one in the case where an effective channel width is used for the calculation is obtained in some cases.

Note that in this specification, the description “A projects as compared with B” may indicate, for example, the case where at least one of end portions of A is positioned on an outer side than at least one of end portions of B in a top view or a cross-sectional view. Thus, the description “A projects as compared with B” can be alternatively referred to as the description “one of end portions of A is positioned on an outer side than one of end portions of B”.

In this specification, the term “parallel” indicates that the angle formed between two straight lines is greater than or equal to −10° and less than or equal to 10°, and accordingly also includes the case where the angle is greater than or equal to −5° and less than or equal to 5° . The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

### <Semiconductor Device>

An example of a semiconductor device of one embodiment of the present invention is shown below.

### <Inverter Circuit>

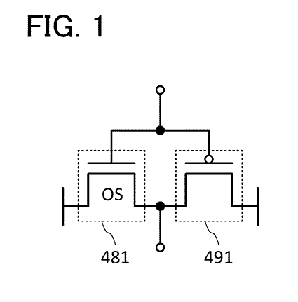

A circuit diagram in FIG. 1 shows a configuration of a so-called inverter circuit in which a p-channel transistor 491 and an n-channel transistor 481 are connected to each other in series and gates of them are connected to each other. An inverter circuit can be used as a logic circuit included in a semiconductor device or a part of the logic circuit. Note that, as the transistor 491, an n-channel transistor may be used in some cases. Furthermore, as the transistor 481, a p-channel transistor may be used in some cases.

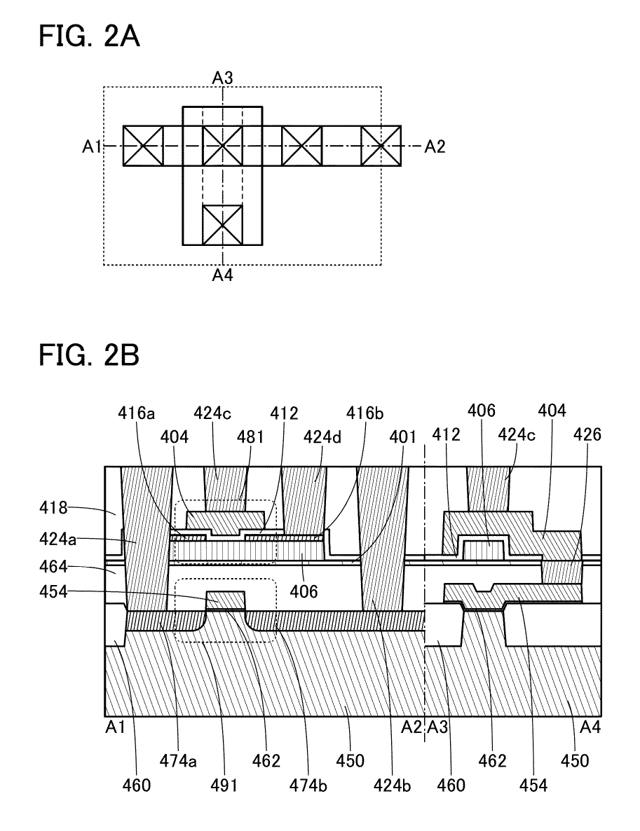

FIG. 2A is a top view of the inverter circuit corresponding to FIG. 1. FIG. 2B is a cross-sectional view taken along dashed-dotted line A1-A2 and dashed-dotted line A3-A4 in FIG. 2A. As illustrated in FIG. 2B, the inverter circuit includes the transistor 491 and the transistor 481 placed above the transistor 491.

In the inverter circuit in FIGS. 2A and 2B, the transistor 491 and the transistor 481 overlap each other, whereby the area occupied by the inverter circuit can be reduced. In addition, a conductor serving as an electrode, a wiring, or the like positioned at an end portion in the inverter circuit is preferably shared with an adjacent logic circuit such as an inverter circuit. Thus, the area of the whole semiconductor device can be reduced.

The transistor 491 in FIG. 2B is a transistor using a semiconductor substrate 450. The transistor 491 includes a region 474a in the semiconductor substrate 450, a region 474b in the semiconductor substrate 450, an insulator 462, and a conductor 454. The conductor 454 is placed over the semiconductor substrate 450 with the insulator 462 provided therebetween. A region where the conductor 454 and the semiconductor substrate 450 overlap each other includes a region not overlapping with the regions 474a and 474b in the semiconductor substrate 450.

Moreover, the semiconductor substrate 450 may include, in the vicinity of the interface with the insulator 462, a region including impurities imparting n-type conductivity at a higher concentration than those in other regions of the semiconductor substrate 450. Thus, the threshold voltage of the transistor 491 can be adjusted.

Accordingly, normally-off electrical characteristics can be easily obtained even when a conductor with a high work function is used as the conductor 454. The conductor with the high work function has higher heat resistance than a conductor with a low work function in many cases, and thus may increase the degree of freedom of later steps and increase performance of the semiconductor device. Moreover, a channel formation region can be set away from the interface between the semiconductor substrate 450 and the insulator 462 in some cases. Therefore, interface scattering, capture of carriers due to the interface state, and the like can be reduced, so that large on-state current and high reliability can be achieved.

In the transistor 491, the regions 474a and 474b have a function as a source region and a drain region. The insulator 462 has a function as a gate insulator. The conductor 454 has a function as a gate electrode. Therefore, resistance of a channel formation region can be controlled by a potential applied to the conductor 454. In other words, conduction or non-conduction between the region 474a and the region 474b can be controlled by the potential applied to the conductor 454.

For the semiconductor substrate 450, a single-material semiconductor substrate of silicon, germanium, or the like or a compound semiconductor substrate of silicon carbide, silicon germanium, gallium arsenide, indium phosphide, zinc oxide, gallium oxide, or the like may be used, for example. A single crystal silicon substrate is preferably used as the semiconductor substrate 450.

For the semiconductor substrate 450, a semiconductor substrate including impurities imparting n-type conductivity is used. However, a semiconductor substrate including impurities imparting p-type conductivity may be used as the semiconductor substrate 450. In that case, a well including impurities imparting the n-type conductivity is provided in a region where the transistor 491 is formed. Alternatively, the semiconductor substrate 450 may be an i-type semiconductor substrate.

A top surface of the semiconductor substrate 450 preferably has a (110) plane. Then, on-state characteristics of the transistor 491 can be improved.

The regions 474a and 474b are regions including impurities imparting the p-type conductivity. Accordingly, the transistor 491 has a structure of a p-channel transistor.

The conductor 454 may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 462 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 462 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

Note that the transistor 491 is separated from an adjacent transistor by an insulator 460 and the like. As the element isolation method, a shallow trench isolation (STI) method, a local oxidation of silicon (LOCOS) method, or the like can be used.

The insulator 460 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum.

The insulator 460 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The transistor 481 in FIG. 2B is a transistor using a semiconductor 406. The transistor 481 includes the semiconductor 406, a conductor 416a, a conductor 416b, an insulator 412, and a conductor 404. The conductors 416a and 416b each have a region in contact with the semiconductor 406. In FIG. 2B, the conductors 416a and 416b each have a region in contact with a top surface of the semiconductor 406. Note that the conductors 416a and 416b may each have a region in contact with a side surface or a bottom surface of the semiconductor 406. The conductor 404 includes a region overlapping with the semiconductor 406 with the insulator 412 provided therebetween, a region overlapping with the conductor 416a with the insulator 412 provided therebetween, and a region overlapping with the conductor 416b with the insulator 412 provided therebetween. In FIG. 2B, the conductor 404 is placed over the semiconductor 406 with the insulator 412 provided therebetween. Furthermore, the conductor 404 is placed over the conductor 416a and the conductor 416b with the insulator 412 provided therebetween.

In the transistor 481, the conductors 416a and 416b have a function as a source electrode and a drain electrode. The insulator 412 has a function as a gate insulator. The conductor 404 has a function as a gate electrode. Therefore, resistance of a channel formation region can be controlled by a potential applied to the conductor 404. In other words, conduction or non-conduction between the conductor 416a and the conductor 416b can be controlled by the potential applied to the conductor 404.

The details of the semiconductor 406 are described later.

Each of the conductor 416a and the conductor 416b may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 412 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 412 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The conductor 404 may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound may be used, for example, and a conductor containing aluminum, a conductor containing copper and titanium, a conductor containing copper and manganese, a conductor containing indium, tin, and oxygen, a conductor containing titanium and nitrogen, or the like may be used.

The inverter circuit in FIG. 2B includes an insulator 464, an insulator 401, an insulator 418, a conductor 424a, a conductor 424b, a conductor 424c, a conductor 424d, and a conductor 426.

The insulator 464 is placed over the transistor 491. The insulator 401 is placed over the insulator 464. The transistor 481 is placed over the insulator 401. The insulator 418 is placed over the transistor 481.

An opening portion reaching the region 474a is provided in the insulator 418, the insulator 412, the conductor 416a, the semiconductor 406, the insulator 401, and the insulator 464. The conductor 424a is embedded in the opening portion. An opening portion reaching the region 474b is provided in the insulator 418, the insulator 412, the insulator 401, and the insulator 464. The conductor 424b is embedded in the opening portion. An opening portion reaching the conductor 404 is provided in the insulator 418. The conductor 424c is embedded in the opening portion. An opening portion reaching the conductor 416b is provided in the insulator 418 and the insulator 412. The conductor 424d is embedded in the opening portion. An opening portion reaching the conductor 454 is provided in the insulator 401 and the insulator 464. The conductor 426 is embedded in the opening portion.

Thus, the transistor 491 is electrically connected to the transistor 481 through the conductor provided in the opening portion. Specifically, the region 474a of the transistor 491 is electrically connected to the conductor 416a of the transistor 481 through the conductor 424a. The conductor 454 of the transistor 491 is electrically connected to the conductor 404 of the transistor 481 through the conductor 426. The conductor 424a reaches the transistor 491 by passing through the transistor 481 and the like; thus, the conductor 424a can be referred to as a through electrode. When the through electrode is included, the transistor 491 and the transistor 481 can overlap each other; thus, the area occupied by the inverter circuit can be reduced. Thus, the integration degree of the semiconductor device including the inverter circuit can be increased.

The insulator 464 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 464 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

Note that the insulator 464 preferably includes an insulator with low relative permittivity. For example, the insulator 464 preferably includes silicon oxide, silicon oxynitride, silicon nitride oxide, silicon nitride, resin, or the like. Alternatively, the insulator 464 preferably has a stacked-layer structure of silicon oxide or silicon oxynitride and resin. When silicon oxide or silicon oxynitride, which is thermally stable, is combined with resin, the stacked-layer structure can have thermal stability and low relative permittivity. Examples of the resin include polyester, polyolefin, polyamide (e.g., nylon or aramid), polyimide, polycarbonate, and acrylic.

When an insulator that has a function of blocking oxygen and impurities such as hydrogen is placed near the transistor 481, the electrical characteristics of the transistor 481 can be stable. For example, the insulator that has a function of blocking oxygen and impurities such as hydrogen is preferably used as the insulator 401.

An insulator with a function of blocking oxygen and impurities such as hydrogen may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used.

The insulator 401 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 401 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 418 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum.

The insulator 418 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

Note that the insulator 418 preferably includes an insulator with low relative permittivity. For example, the insulator 418 preferably includes silicon oxide, silicon oxynitride, silicon nitride oxide, silicon nitride, resin, or the like. Alternatively, the insulator 418 preferably has a stacked-layer structure of silicon oxide or silicon oxynitride and resin. When silicon oxide or silicon oxynitride, which is thermally stable, is combined with resin, the stacked-layer structure can have thermal stability and low relative permittivity. Examples of the resin include polyester, polyolefin, polyamide (e.g., nylon or aramid), polyimide, polycarbonate, and acrylic.

Each of the conductors 424a, 424b, 424c, and 424d may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound may be used, for example, and a conductor containing aluminum, a conductor containing copper and titanium, a conductor containing copper and manganese, a conductor containing indium, tin, and oxygen, a conductor containing titanium and nitrogen, or the like may be used. Alternatively, for example, a stacked-layer structure of titanium nitride and tungsten over the titanium nitride may be used.

The conductor 426 may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound may be used, for example, and a conductor containing aluminum, a conductor containing copper and titanium, a conductor containing copper and manganese, a conductor containing indium, tin, and oxygen, a conductor containing titanium and nitrogen, or the like may be used. Alternatively, for example, a stacked-layer structure of titanium nitride and tungsten over the titanium nitride may be used.

### Modification Example 1 of Inverter Circuit

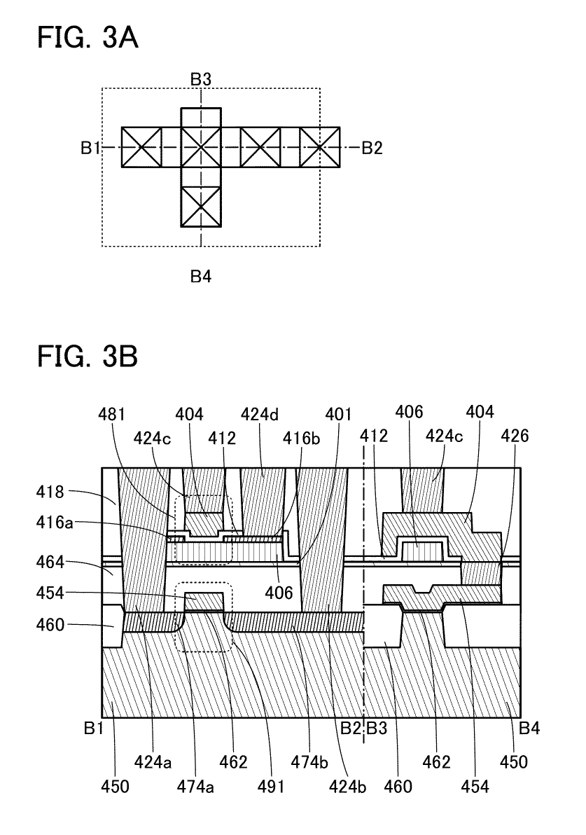

FIG. 3A is a top view of the inverter circuit corresponding to FIG. 1. FIG. 3B is a cross-sectional view taken along dashed-dotted line B1-B2 and dashed-dotted line B3-B4 in FIG. 3A.

In the inverter circuit in FIGS. 3A and 3B, the conductor 404 of the transistor 481 is smaller than that in the inverter circuit in FIGS. 2A and 2B. Therefore, the area occupied by the inverter circuit in FIGS. 3A and 3B can be smaller than that in FIGS. 2A and 2B. Moreover, when the distance between the components is reduced to half the minimum feature size, the area occupied by the inverter circuit can be much smaller. Thus, the area of the whole semiconductor device can be reduced.

Note that the description of the inverter circuit in FIGS. 2A and 2B is referred to for the other structures.

### Modification Example 2 of Inverter Circuit

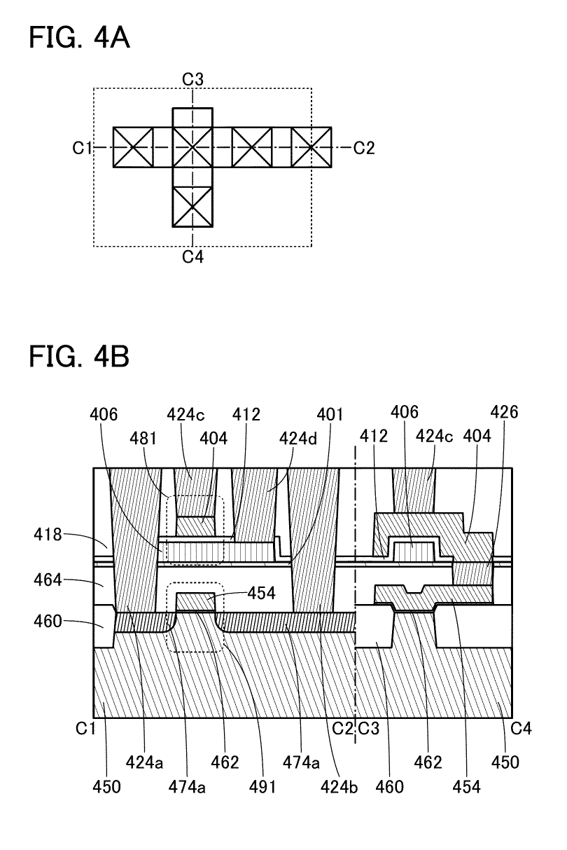

FIG. 4A is a top view of the inverter circuit corresponding to FIG. 1. FIG. 4B is a cross-sectional view taken along dashed-dotted line C1-C2 and dashed-dotted line C3-C4 in FIG. 4A.

The inverter circuit in FIGS. 4A and 4B is different from that in FIGS. 3A and 3B in that the conductor 416a and the conductor 416b of the transistor 481 are omitted. The area occupied by the inverter circuit in FIGS. 4A and 4B can be substantially equal to that in FIGS. 3A and 3B. Thus, the area occupied by the inverter circuit in FIGS. 4A and 4B can be smaller than that in the semiconductor device in FIGS. 2A and 2B.

Note that the description of the inverter circuit in FIGS. 2A and 2B is referred to for the other structures.

### Modification Example 3 of Inverter Circuit

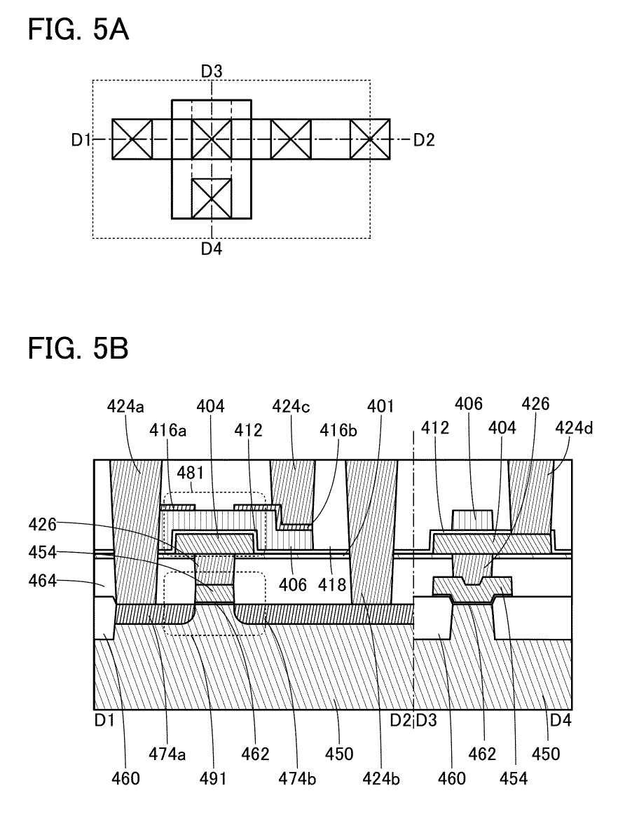

FIG. 5A is a top view of the inverter circuit corresponding to FIG. 1. FIG. 5B is a cross-sectional view taken along dashed-dotted line D1 -D2 and dashed-dotted line D3-D4 in FIG. 5A.

The inverter circuit in FIGS. 5A and 5B is different from those in FIGS. 2A and 2B, FIGS. 3A and 3B, and FIGS. 4A and 4B in the positional relationship between the conductor 404, the semiconductor 406, and the insulator 412 of the transistor 481. Thus, the area of the whole semiconductor device can be reduced.

The transistor 481 in FIG. 5B is a transistor using the semiconductor 406. The transistor 481 includes the semiconductor 406, the conductor 416a, the conductor 416b, the insulator 412, and the conductor 404. The conductors 416a and 416b each have a region in contact with the semiconductor 406. In FIG. 5B, the conductors 416a and 416b each have a region in contact with a top surface of the semiconductor 406. Note that the conductors 416a and 416b may each have a region in contact with a side surface or a bottom surface of the semiconductor 406. The conductor 404 includes a region overlapping with the semiconductor 406 with the insulator 412 provided therebetween, a region overlapping with the conductor 416a with the insulator 412 provided therebetween, and a region overlapping with the conductor 416b with the insulator 412 and the semiconductor 406 provided therebetween. In FIG. 5B, the conductor 404 is placed under the semiconductor 406 with the insulator 412 and the semiconductor 406 provided therebetween. Furthermore, the conductor 404 is placed under the conductor 416a and the conductor 416b with the insulator 412 and the semiconductor 406 provided therebetween.

The inverter circuit in FIG. 5B includes an insulator 464, an insulator 401, an insulator 418, a conductor 424a, a conductor 424b, a conductor 424c, a conductor 424d, and a conductor 426.

The insulator 464 is placed over the transistor 491. The insulator 401 is placed over the insulator 464. The transistor 481 is placed over the insulator 401. The insulator 418 is placed over the transistor 481.

An opening portion reaching the region 474a is provided in the insulator 418, the insulator 412, the conductor 416a, the semiconductor 406, the insulator 401, and the insulator 464. The conductor 424a is embedded in the opening portion. An opening portion reaching the region 474b is provided in the insulator 418, the insulator 412, the insulator 401, and the insulator 464. The conductor 424b is embedded in the opening portion. An opening portion reaching the conductor 416b is provided in the insulator 418. The conductor 424c is embedded in the opening portion. An opening portion reaching the conductor 404 is provided in the insulator 418 and the insulator 412. The conductor 424d is embedded in the opening portion. An opening portion reaching the conductor 454 is provided in the insulator 401 and the insulator 464. The conductor 426 is embedded in the opening portion.

Thus, the transistor 491 is electrically connected to the transistor 481 through the conductor provided in the opening portion. Specifically, the region 474a of the transistor 491 is electrically connected to the conductor 416a of the transistor 481 through the conductor 424a. The conductor 454 of the transistor 491 is electrically connected to the conductor 404 of the transistor 481 through the conductor 426. The conductor 424a reaches the transistor 491 by passing through the transistor 481 and the like; thus, the conductor 424a can be referred to as a through electrode. When the through electrode is included, the transistor 491 and the transistor 481 can overlap each other; thus, the area occupied by the inverter circuit can be reduced. Thus, the integration degree of the semiconductor device including the inverter circuit can be increased.

Note that the description of the inverter circuit in FIGS. 2A and 2B is referred to for the other structures.

### Modification Example 4 of Inverter Circuit

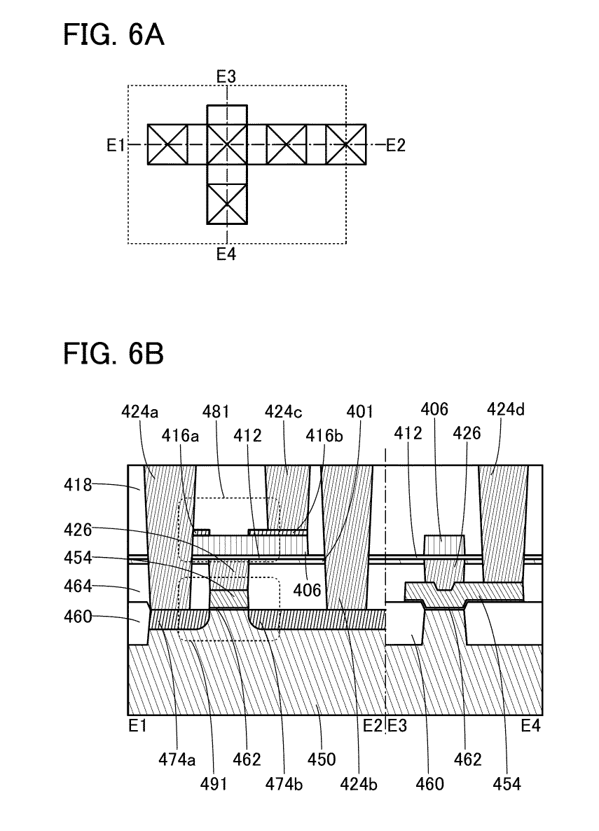

FIG. 6A is a top view of the inverter circuit corresponding to FIG. 1. FIG. 6B is a cross-sectional view taken along dashed-dotted line E1-E2 and dashed-dotted line E3-E4 in FIG. 6A.

The inverter circuit in FIGS. 6A and 6B is different from that in FIGS. 5A and 5B in that the conductor 404 of the transistor 481 is not included. Thus, the area of the whole semiconductor device can be reduced.

In the inverter circuit in FIGS. 6A and 6B, the conductor 426 has a function as the gate electrode of the transistor 481.

Note that the description of the inverter circuit in FIGS. 2A and 2B or FIGS. 5A and 5B is referred to for the other structures.

### Modification Example 5 of Inverter Circuit

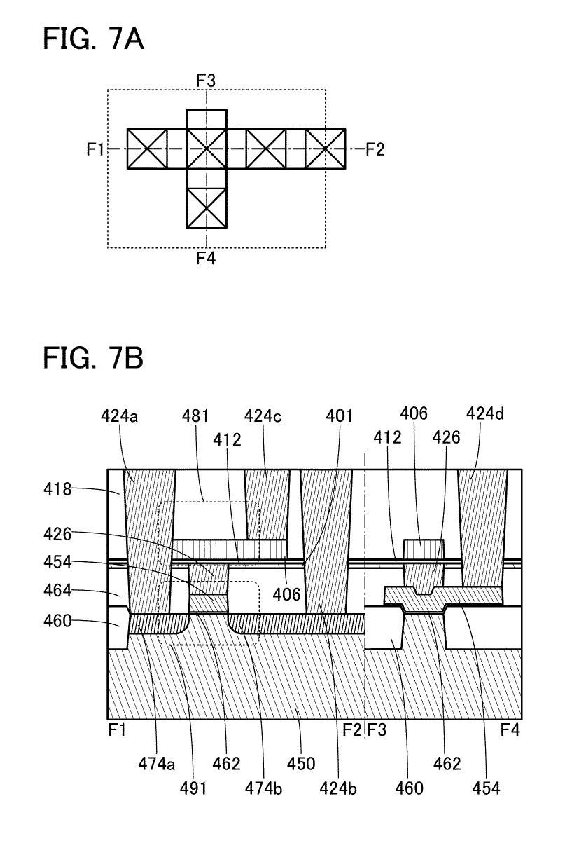

FIG. 7A is a top view of the inverter circuit corresponding to FIG. 1. FIG. 7B is a cross-sectional view taken along dashed-dotted line F1-F2 and dashed-dotted line F3-F4 in FIG. 7A.

The inverter circuit in FIGS. 7A and 7B is different from that in FIGS. 6A and 6B in that the conductor 416a and the conductor 416b of the transistor 481 are not included. Thus, the area of the whole semiconductor device can be reduced.

Note that the description of the inverter circuit in FIGS. 2A and 2B, FIGS. 5A and 5B, or FIGS. 6A and 6B is referred to for the other structures.

### Modification Example 6 of Inverter Circuit

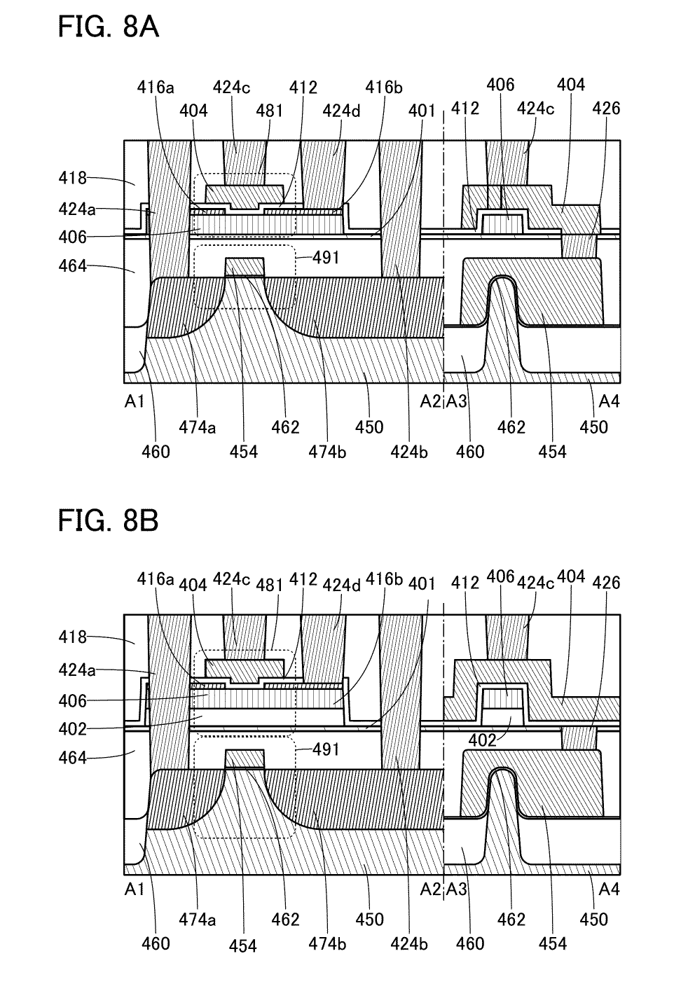

FIG. 8A is a cross-sectional view of the inverter circuit corresponding to FIG. 1. FIG. 8A is taken along dashed-dotted line A1-A2 and dashed-dotted line A3-A4 in FIG. 2A.

The inverter circuit in FIG. 8A is different from that in FIG. 2B in that the channel formation region of the transistor 491 has a fin shape. Thus, the area of the whole semiconductor device can be reduced.

Note that the description of the inverter circuit in FIGS. 2A and 2B is referred to for the other structures.

### Modification Example 7 of Inverter Circuit

FIG. 8B is a cross-sectional view of the inverter circuit corresponding to FIG. 1. FIG. 8B is taken along dashed-dotted line A1-A2 and dashed-dotted line A3-A4 in FIG. 2A.

The inverter circuit in FIG. 8B is different from that in FIG. 8A in that the channel formation region of the transistor 481 is surrounded by an electric field of the conductor 404. In the inverter circuit in FIG. 8B, an insulator 402 is provided between the insulator 401 and the semiconductor 406 of the transistor 481. Accordingly, because of the height of the insulator 402, the conductor 404 is placed even at a lower position than the interface between the semiconductor 406 and the insulator 402. A structure in which a semiconductor is electrically surrounded by an electric field of a gate electrode as described above is referred to as a surrounded channel (s-channel) structure. Therefore, a channel is formed in the entire semiconductor 406 (bulk) in some cases. In the s-channel structure, a large amount of current can flow between a source and a drain of the transistor, so that an on-state current can be increased. In addition, since the semiconductor 406 is surrounded by the electric field of the conductor 404, an off-state current can be decreased. Therefore, the operation speed of the semiconductor device can be increased.

The insulator 402 is preferably an insulator containing excess oxygen.

The insulator containing excess oxygen means an insulator from which oxygen is released by heat treatment, for example. The silicon oxide layer containing excess oxygen means a silicon oxide layer which can release oxygen by heat treatment or the like, for example. Therefore, the insulator 402 is an insulator in which oxygen can be moved. In other words, the insulator 402 may be an insulator having an oxygen-transmitting property. For example, the insulator 402 may be an insulator having a higher oxygen-transmitting property than the semiconductor 406.

The insulator containing excess oxygen has a function of reducing oxygen vacancies in the semiconductor 406 in some cases. Such oxygen vacancies form DOS in the semiconductor 406 and serve as hole traps or the like. In addition, hydrogen comes into the site of such oxygen vacancies and forms electrons serving as carriers. Therefore, by reducing the oxygen vacancies in the semiconductor 406, the transistor can have stable electrical characteristics.

Here, an insulator from which oxygen is released by heat treatment may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in TDS analysis in the range of a surface temperature of 100° C. to 700° C. or 100° C. to 500° C.

Here, the method for measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having the mass-to-charge ratio of 32, is not taken into consideration because it is unlikely to be present. Furthermore, an oxygen molecule including an oxygen atom having a mass number of 17 or 18 which is an isotope of an oxygen atom is also not taken into consideration because the proportion of such a molecule in the natural world is minimal

N_{O2}=N_{H2}/S_{H2}×S_{O2}×α

The value N_{H2} is obtained by conversion of the number of hydrogen molecules desorbed from the reference sample into densities. The value S_{H2} is the integral value of ion intensity in the case where the reference sample is subjected to the TDS analysis. Here, the reference value of the reference sample is set to N_{H2}/S_{H2}. The value S_{O2} is the integral value of ion intensity when the measurement sample is analyzed by TDS. The value a is a coefficient affecting the ion intensity in the TDS analysis. Refer to Japanese Published Patent Application No. H6-275697 for details of the above formula. The amount of released oxygen is measured with a thermal desorption spectroscopy apparatus produced by ESCO Ltd., EMD-WA1000S/W using a silicon substrate containing hydrogen atoms at 1×10¹⁶ atoms/cm², for example, as the reference sample.

Furthermore, in the TDS analysis, oxygen is partly detected as an oxygen atom. The ratio between oxygen molecules and oxygen atoms can be calculated from the ionization rate of the oxygen molecules. Note that since the above a includes the ionization rate of the oxygen molecules, the amount of the released oxygen atoms can also be estimated through the evaluation of the amount of the released oxygen molecules.

Note that N_{O2} is the amount of the released oxygen molecules. The amount of released oxygen in the case of being converted into oxygen atoms is twice the amount of the released oxygen molecules.

Furthermore, the insulator from which oxygen is released by heat treatment may contain a peroxide radical. Specifically, the spin density attributed to the peroxide radical is greater than or equal to 5×10¹⁷ spins/cm³. Note that the insulator containing a peroxide radical may have an asymmetric signal with a g factor of approximately 2.01 in ESR.

The insulator containing excess oxygen may be formed using oxygen-excess silicon oxide (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

Note that the description of the inverter circuit in FIGS. 2A and 2B is referred to for the other structures.

### Modification Example 8 of Inverter Circuit

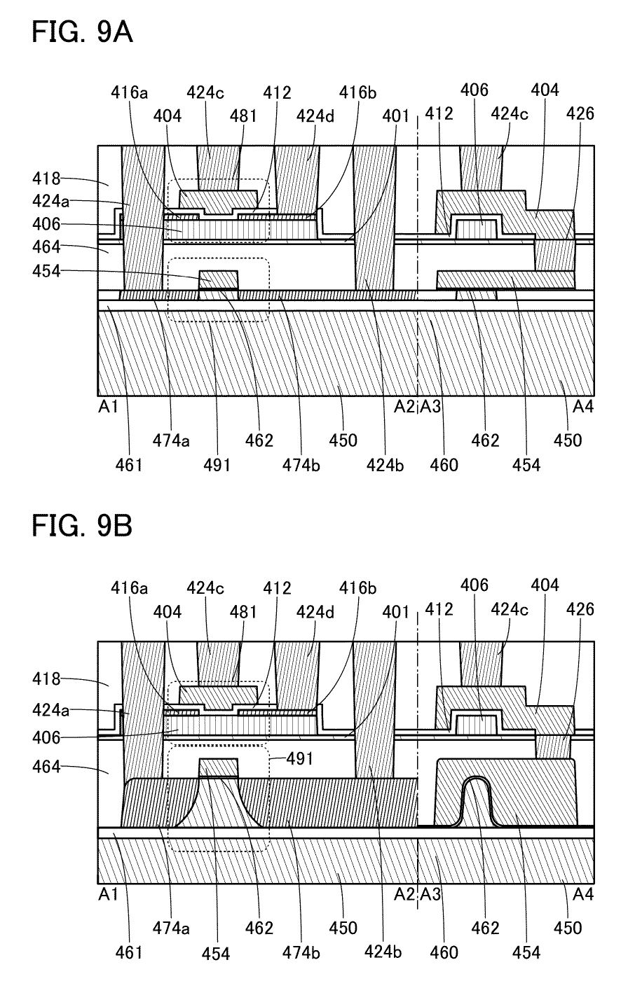

FIG. 9A is a cross-sectional view of the inverter circuit corresponding to FIG. 1. FIG. 9A is taken along dashed-dotted line A1-A2 and dashed-dotted line A3-A4 in FIG. 2A.

The inverter circuit in FIG. 8A is different from that in FIG. 2B in that the semiconductor substrate 450 of the transistor 491 is a silicon on insulator (SOI) substrate. Since the SOI substrate is used as the semiconductor substrate 450, a punch-through current and the like can be reduced; and thus the off-state current of the transistor 491 can be reduced. Note that the insulator 461 can be formed by turning part of the semiconductor substrate 450 into an insulator. For example, silicon oxide can be used as the insulator 452. Thus, power consumption of the semiconductor device can be low.

Note that the description of the inverter circuit in FIGS. 2A and 2B is referred to for the other structures.

### Modification Example 9 of Inverter Circuit

FIG. 9B is a cross-sectional view of the inverter circuit corresponding to FIG. 1. FIG. 9B is taken along dashed-dotted line A1-A2 and dashed-dotted line A3-A4 in FIG. 2A.

The inverter circuit in FIG. 9B is different from that in FIG. 9A in that the channel formation region of the transistor 491 has a fin shape. Since the SOI substrate is used as the semiconductor substrate 450, a punch-through current and the like can be reduced; and thus the off-state current of the transistor 491 can be reduced. Note that the insulator 461 can be formed by turning part of the semiconductor substrate 450 into an insulator. For example, silicon oxide can be used as the insulator 452. Thus, power consumption of the semiconductor device can be low. Furthermore, the operation speed of the semiconductor device can be increased.

Note that the description of the inverter circuit in FIGS. 2A and 2B, FIG. 8A, or FIG. 9A is referred to for the other structures.

As described above, the inverter circuit of one embodiment of the present invention can have a variety of structures. The structures described above are examples. Thus, a novel inverter circuit can be formed by combining a part of one structure and a part of another structure.

### <Semiconductor>

The semiconductor 406 is described below.

An oxide semiconductor is preferably used as the semiconductor 406. However, silicon (including strained silicon), germanium, silicon germanium, silicon carbide, gallium arsenide, aluminum gallium arsenide, indium phosphide, gallium nitride, an organic semiconductor, or the like can be used in some cases.

### <Structure of Oxide Semiconductor>

A structure of an oxide semiconductor is described below.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

It is known that an amorphous structure is generally defined as being metastable and unfixed, and being isotropic and having no non-uniform structure. In other words, an amorphous structure has a flexible bond angle and a short-range order but does not have a long-range order.

This means that an inherently stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. Note that an a-like OS has a periodic structure in a microscopic region, but at the same time has a void and has an unstable structure. For this reason, an a-like OS has physical properties similar to those of an amorphous oxide semiconductor.

### <CAAC-OS>

First, a CAAC-OS is described.

A CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

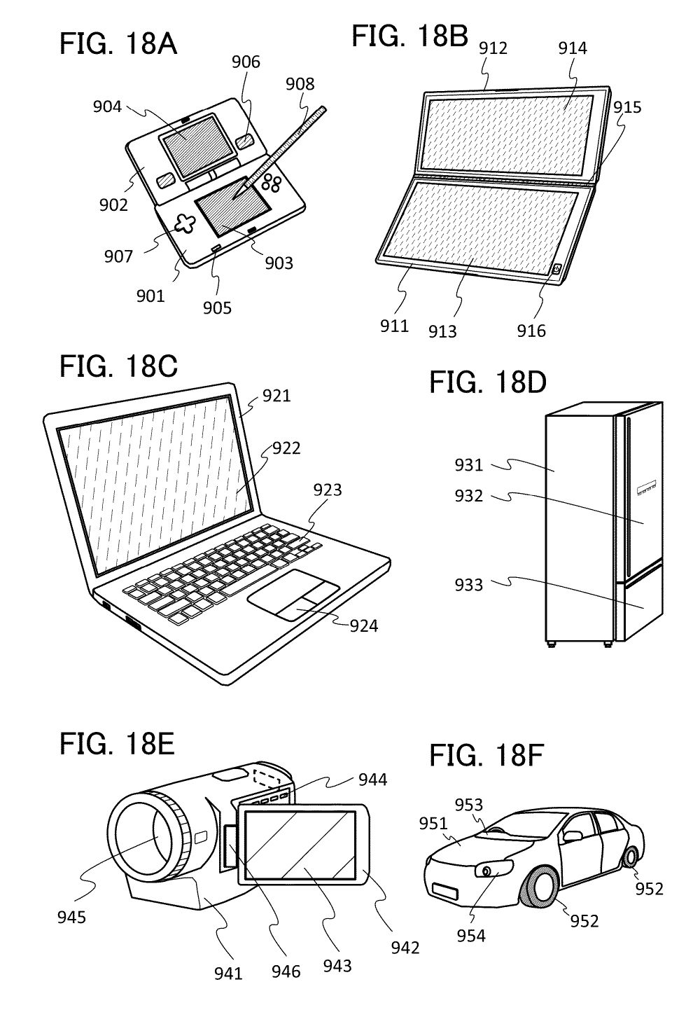

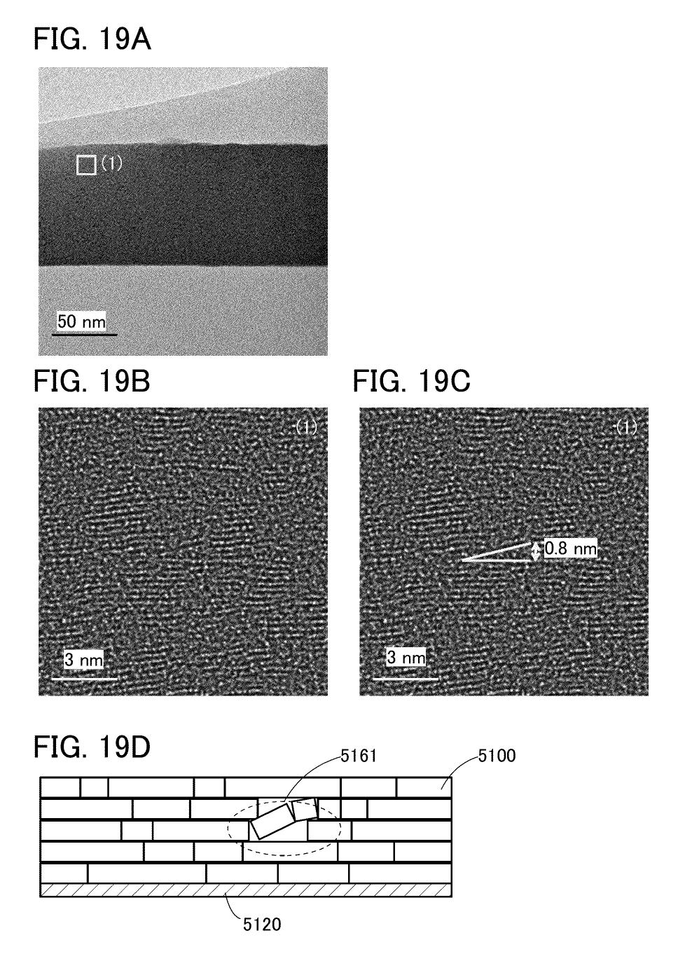

A CAAC-OS observed with TEM is described below. FIG. 19A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 19B is an enlarged Cs-corrected high-resolution TEM image of a region (1) in FIG. 19A. FIG. 19B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 19B, the CAAC-OS has a characteristic atomic arrangement. The characteristic atomic arrangement is denoted by an auxiliary line in FIG. 19C. FIGS. 19B and 19C prove that the size of a pellet is 1 nm or greater, or 3 nm or greater, and the size of a space caused by tilt of the pellets is approximately 0.8 nm. Therefore, the pellet can also be referred to as a nanocrystal (nc). Furthermore, the CAAC-OS can also be referred to as an oxide semiconductor including c-axis aligned nanocrystals (CANC).

Here, according to the Cs-corrected high-resolution TEM images, the schematic arrangement of pellets 5100 of a CAAC-OS over a substrate 5120 is illustrated by such a structure in which bricks or blocks are stacked (see FIG. 19D). The part in which the pellets are tilted as observed in FIG. 19C corresponds to a region 5161 shown in FIG. 19D.

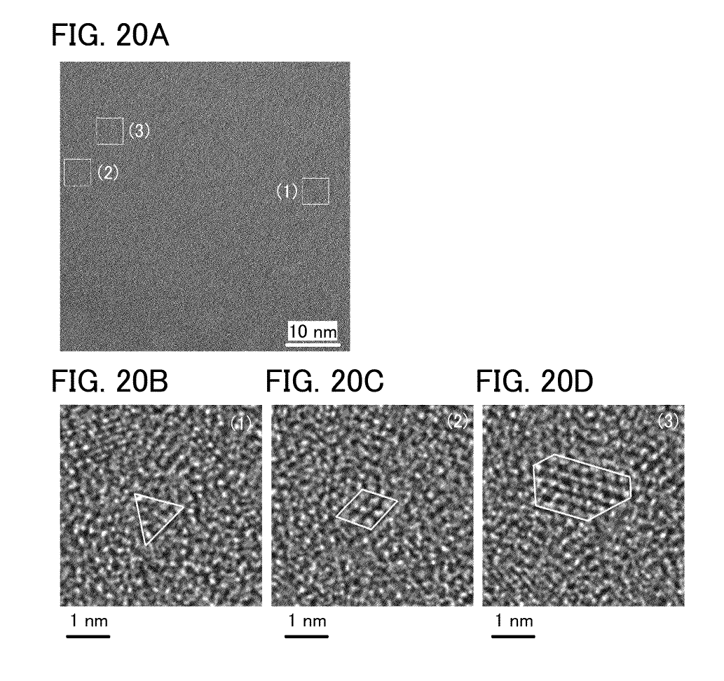

FIG. 20A shows a Cs-corrected high-resolution TEM image of a plane of the CAAC-OS observed from a direction substantially perpendicular to the sample surface. FIGS. 20B, 20C, and 20D are enlarged Cs-corrected high-resolution TEM images of regions (1), (2), and (3) in FIG. 20A, respectively. FIGS. 20B, 20C, and 20D indicate that metal atoms are arranged in a triangular, quadrangular, or hexagonal configuration in a pellet. However, there is no regularity of arrangement of metal atoms between different pellets.

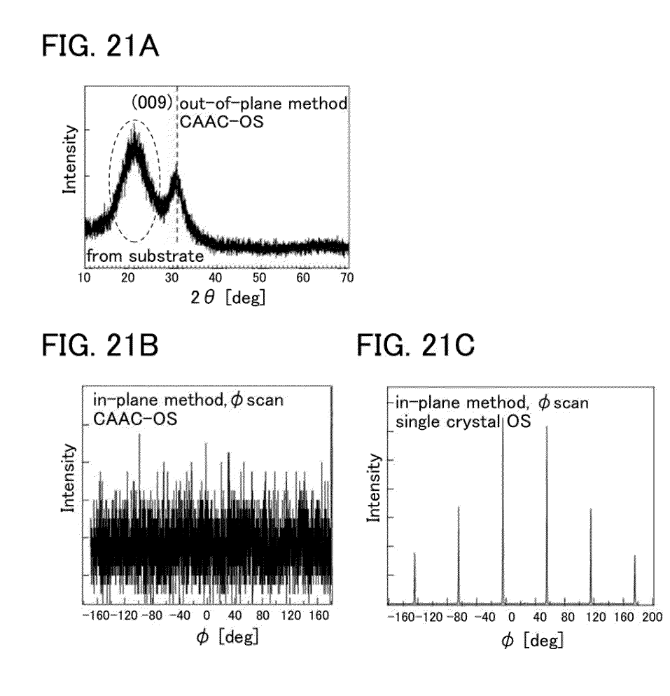

Next, a CAAC-OS analyzed by X-ray diffraction (XRD) is described. For example, when the structure of a CAAC-OS including an InGaZnO₄ crystal is analyzed by an out-of-plane method, a peak appears at a diffraction angle (2θ) of around 31° as shown in FIG. 21A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS by an out-of-plane method, another peak may appear when 2θ is around 36°, in addition to the peak at 2 θ of around 31°. The peak at 2θ of around 36° indicates that a crystal having no c-axis alignment is included in part of the CAAC-OS. It is preferable that in the CAAC-OS analyzed by an out-of-plane method, a peak appear when 2 θ is around 31° and that a peak not appear when 2 θ is around 36°.

On the other hand, in structural analysis of the CAAC-OS by an in-plane method in which an X-ray beam is incident on a sample in a direction substantially perpendicular to the c-axis, a peak appears when 2 θ is around 56°. This peak is attributed to the (110) plane of the InGaZnO4 crystal. In the case of the CAAC-OS, when analysis (φ scan) is performed with 2 θ fixed at around 56° and with the sample rotated using a normal vector of the sample surface as an axis (φ axis), as shown in FIG. 21B, a peak is not clearly observed. In contrast, in the case of a single crystal oxide semiconductor of InGaZnO₄, when φ scan is performed with 2 θ fixed at around 56°,as shown in FIG. 21C, six peaks which are derived from crystal planes equivalent to the (110) plane are observed. Accordingly, the structural analysis using XRD shows that the directions of a-axes and b-axes are irregularly oriented in the CAAC-OS.

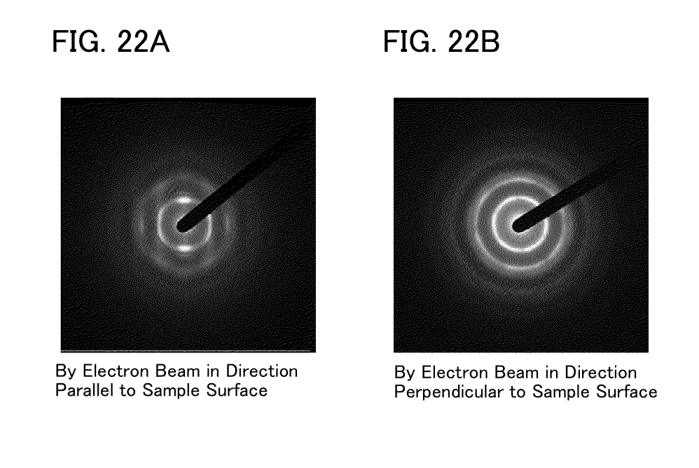

Next, a CAAC-OS analyzed by electron diffraction is described. For example, when an electron beam with a probe diameter of 300 nm is incident on a CAAC-OS including an InGaZnO₄ crystal in a direction parallel to the sample surface, a diffraction pattern (also referred to as a selected-area transmission electron diffraction pattern) shown in FIG. 22A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 22B shows a diffraction pattern obtained in such a manner that an electron beam with a probe diameter of 300 nm is incident on the same sample in a direction perpendicular to the sample surface. As shown in FIG. 22B, a ring-like diffraction pattern is observed. Thus, the electron diffraction also indicates that the a-axes and b-axes of the pellets included in the CAAC-OS do not have regular alignment. The first ring in FIG. 22B is considered to be derived from the (010) plane, the (100) plane, and the like of the InGaZnO₄ crystal. The second ring in FIG. 22B is considered to be derived from the (110) plane and the like.

As described above, the CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. Furthermore, oxygen vacancies in the oxide semiconductor serve as carrier traps or serve as carrier generation sources when hydrogen is captured therein.

The CAAC-OS having small amounts of impurities and oxygen vacancies is an oxide semiconductor with low carrier density. Specifically, an oxide semiconductor with a carrier density of lower than 8×10¹¹/cm³, preferably lower than 1×10¹¹/cm³, further preferably lower than 1×10¹⁰/cm³, and higher than or equal to 1×10⁻⁹/cm³ can be used. Such an oxide semiconductor is referred to as a highly purified intrinsic or substantially highly purified intrinsic oxide semiconductor. A CAAC-OS has a low impurity concentration and a low density of defect states. Thus, the CAAC-OS can be referred to as an oxide semiconductor having stable characteristics.

<nc-OS>

Next, an nc-OS will be described.

An nc-OS has a region in which a crystal part is observed and a region in which a crystal part is not clearly observed in a high-resolution TEM image. In most cases, the size of a crystal part included in the nc-OS is greater than or equal to 1 nm and less than or equal to 10 nm, or greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not ordered. Accordingly, the nc-OS cannot be distinguished from an a-like OS or an amorphous oxide semiconductor, depending on an analysis method. For example, when the nc-OS is analyzed by an out-of-plane method using an X-ray beam having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet. Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots is shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

<a-like OS>

An a-like OS has a structure intermediate between those of the nc-OS and the amorphous oxide semiconductor.

In a high-resolution TEM image of the a-like OS, a void may be observed. Furthermore, in the high-resolution TEM image, there are a region where a crystal part is clearly observed and a region where a crystal part is not observed.

The a-like OS has an unstable structure because it contains a void. To verify that an a-like OS has an unstable structure as compared with a CAAC-OS and an nc-OS, a change in structure caused by electron irradiation is described below.

An a-like OS (referred to as Sample A), an nc-OS (referred to as Sample B), and a CAAC-OS (referred to as Sample C) are prepared as samples subjected to electron irradiation. Each of the samples is an In-Ga-Zn oxide.

First, a high-resolution cross-sectional TEM image of each sample is obtained. The high-resolution cross-sectional TEM images show that all the samples have crystal parts.

Note that which part is regarded as a crystal part is determined as follows. It is known that a unit cell of an InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

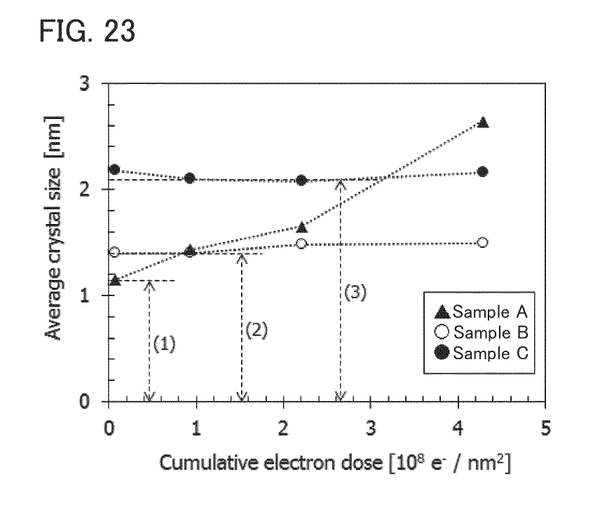

FIG. 23 shows change in the average size of crystal parts (at 22 points to 45 points) in each sample. Note that the crystal part size corresponds to the length of a lattice fringe. FIG. 23 indicates that the crystal part size in the a-like OS increases with an increase in the cumulative electron dose. Specifically, as shown by (1) in FIG. 23, a crystal part of approximately 1.2 nm (also referred to as an initial nucleus) at the start of TEM observation grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 23, the average crystal sizes in an nc-OS and a CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal structure. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more of an amorphous oxide semiconductor, an a-like OS, an nc-OS, and a CAAC-OS, for example.

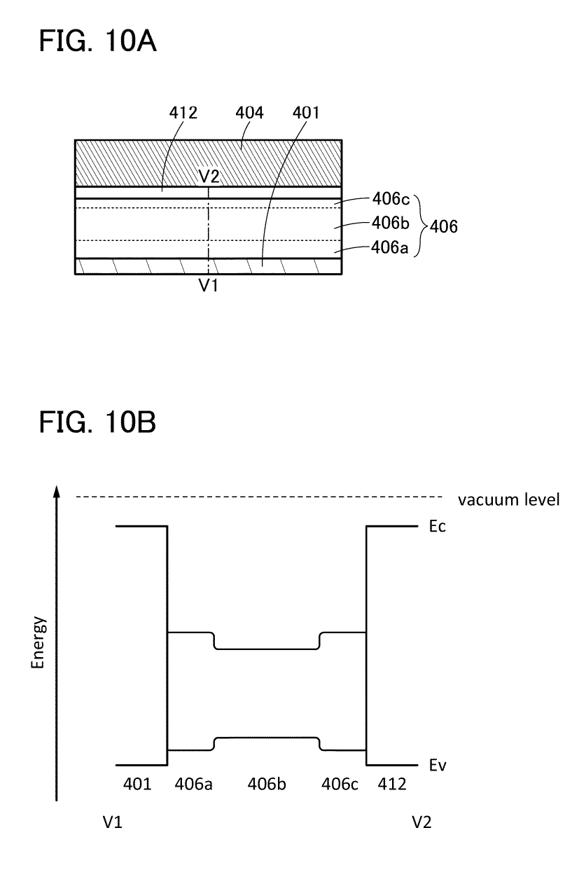

FIG. 10A is an enlarged cross-sectional view of a part of the transistor 481 (the insulator 401, the semiconductor 406, the insulator 412, and the conductor 404). In FIG. 10A, the semiconductor 406 is a stacked-layer film in which a semiconductor layer 406a, a semiconductor layer 406b, and a semiconductor layer 406c are stacked in this order. Note that the semiconductor layer 406c may be a part of the insulator 412. Furthermore, the semiconductor layer 406a may be a part of the insulator 401.

A semiconductor which can be used as the semiconductor layer 406a, the semiconductor layer 406b, the semiconductor layer 406c, or the like is described below.

The semiconductor layer 406b is an oxide semiconductor containing indium, for example. The semiconductor layer 406b can have high carrier mobility (electron mobility) by containing indium, for example. The semiconductor layer 406b preferably contains an element M. The element M is preferably aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that two or more of the above elements may be used in combination as the element M. The element M is an element having a high bonding energy with oxygen, for example. The element M is an element whose bonding energy with oxygen is higher than that of indium, for example. The element M is an element that can increase the energy gap of the oxide semiconductor, for example. Furthermore, the semiconductor layer 406b preferably contains zinc. When the oxide semiconductor contains zinc, the oxide semiconductor is easily to be crystallized in some cases.

Note that the semiconductor layer 406b is not limited to the oxide semiconductor containing indium. The semiconductor layer 406b may be, for example, an oxide semiconductor which does not contain indium and contains zinc, an oxide semiconductor which does not contain indium and contains gallium, or an oxide semiconductor which does not contain indium and contains tin, e.g., a zinc tin oxide, a gallium tin oxide, or gallium oxide.

For the semiconductor layer 406b, an oxide with a wide energy gap may be used. For example, the energy gap of the semiconductor layer 406b is greater than or equal to 2.5 eV and less than or equal to 4.2 eV, preferably greater than or equal to 2.8 eV and less than or equal to 3.8 eV, or further preferably greater than or equal to 3 eV and less than or equal to 3.5 eV.

For example, the semiconductor layer 406a and the semiconductor layer 406c include one or more elements other than oxygen included in the semiconductor layer 406b. Since the semiconductor layer 406a and the semiconductor layer 406c each include one or more elements other than oxygen included in the semiconductor layer 406b, an interface state is less likely to be formed at the interface between the semiconductor layer 406a and the semiconductor layer 406b and the interface between the semiconductor layer 406b and the semiconductor layer 406c.

The case where the semiconductor layer 406a, the semiconductor layer 406b, and the semiconductor layer 406c each include indium is described below. In the case of using an In-M-Zn oxide as the oxide semiconductor layer 406a, assuming that a summation of In and M is 100 atomic %, the proportions of In and M are preferably set to be less than 50 atomic % and greater than or equal to 50 atomic %, respectively, and are further preferably set to less than 25 atomic % and greater than or equal to 75 atomic %, respectively. In the case of using an In—M—Zn oxide as the oxide semiconductor layer 406b, assuming that a summation of In and M is 100 atomic %, the proportions of In and M are preferably set to be greater than or equal to 25 atomic % and less than 75 atomic %, respectively, further preferably greater than or equal to 34 atomic % and less than 66 atomic %, respectively. In the case of using an In—M—Zn oxide as the oxide semiconductor layer 406c, assuming that a summation of In and M is 100 atomic %, the proportions of In and M are preferably set to be less than 50 atomic % and greater than or equal to 50 atomic %, respectively, further preferably less than 25 atomic % and greater than or equal to 75 atomic %, respectively. Note that the semiconductor layer 406c may be an oxide that is a type the same as that of the semiconductor layer 406a.

As the semiconductor layer 406b, an oxide having an electron affinity higher than those of the semiconductor layers 406a and 406c is used. For example, as the semiconductor layer 406b, an oxide having an electron affinity higher than those of the semiconductor layers 406a and 406c by 0.07 eV or higher and 1.3 eV or lower, preferably 0.1 eV or higher and 0.7 eV or lower, or further preferably 0.15 eV or higher and 0.4 eV or lower is used. Note that the electron affinity refers to an energy gap between the vacuum level and the bottom of the conduction band.

An indium gallium oxide has a small electron affinity and a high oxygen-blocking property. Therefore, the semiconductor layer 406c preferably includes indium gallium oxide. The gallium atomic ratio [Ga/(In+Ga)] is, for example, higher than or equal to 70%, preferably higher than or equal to 80%, or more preferably higher than or equal to 90%.

Note that the semiconductor layer 406a and/or the semiconductor layer 406c may be gallium oxide. For example, when gallium oxide is used for the semiconductor layer 406c, a leakage current generated between the conductor 404 and the conductor 416a or 416b can be reduced. In other words, the off-state current of the transistor 481 can be reduced.

At this time, when a gate voltage is applied, a channel is formed in the semiconductor layer 406b having the highest electron affinity among the semiconductor layer 406a, the semiconductor layer 406b, and the semiconductor layer 406c.

FIG. 10B is a band diagram taken along dashed-dotted line V1-V2 in FIG. 10A. FIG. 10B shows a vacuum level (denoted by vacuum level), and an energy of the bottom of the conduction band (denoted by Ec) and an energy of the top of the valence band (denoted by Ev) of each of the layers.

Here, in some cases, there is a mixed region of the semiconductor layer 406a and the semiconductor layer 406b between the semiconductor layer 406a and the semiconductor layer 406b. Furthermore, in some cases, there is a mixed region of the semiconductor layer 406b and the semiconductor layer 406c between the semiconductor layer 406b and the semiconductor layer 406c. The mixed region has a low density of interface states. For that reason, the stack of the semiconductor layer 406a, the semiconductor layer 406b, and the semiconductor layer 406c has a band structure where energy at each interface and in the vicinity of the interface is changed continuously (continuous junction).

At this time, electrons move mainly in the semiconductor layer 406b, not in the semiconductor layers 406a and 406c. Thus, when the interface state density at the interface between the semiconductor layer 406a and the semiconductor layer 406b and the interface state density at the interface between the semiconductor layer 406b and the semiconductor layer 406c are decreased, electron movement in the semiconductor layer 406b is less likely to be inhibited and the on-sate current of the transistor 481 can be increased.

In the case where the transistor 481 has an s-channel structure, a channel is formed in the whole of the semiconductor layer 406b. Therefore, as the semiconductor layer 406b has a larger thickness, a channel region becomes larger. In other words, the thicker the semiconductor layer 406b is, the larger the on-state current of the transistor 481 is. For example, the semiconductor layer 406b has a region with a thickness of greater than or equal to 2 θ nm, preferably greater than or equal to 40 nm, more preferably greater than or equal to 60 nm, or still more preferably greater than or equal to 100 nm. Note that the semiconductor layer 406b has a region with a thickness of, for example, less than or equal to 300 nm, preferably less than or equal to 200 nm, or more preferably less than or equal to 150 nm because the productivity of the semiconductor device including the transistor 481 might be decreased.

Moreover, the thickness of the semiconductor layer 406c is preferably as small as possible to increase the on-state current of the transistor 481. The thickness of the semiconductor layer 406c is less than 10 nm, preferably less than or equal to 5 nm, more preferably less than or equal to 3 nm, for example. Meanwhile, the semiconductor layer 406c has a function of blocking elements other than oxygen (such as hydrogen and silicon) included in the adjacent insulator from entering the semiconductor layer 406b where a channel is formed. For this reason, it is preferable that the oxide semiconductor layer 406c have a certain thickness. The thickness of the semiconductor layer 406c is greater than or equal to 0.3 nm, preferably greater than or equal to 1 nm, more preferably greater than or equal to 2 nm, for example. The semiconductor layer 406c preferably has an oxygen blocking property to suppress outward diffusion of oxygen released from the insulator 402 and the like.

To improve reliability, preferably, the thickness of the semiconductor layer 406a is large and the thickness of the semiconductor layer 406c is small. For example, the semiconductor layer 406a has a region with a thickness of, for example, greater than or equal to 10 nm, preferably greater than or equal to 2 θ nm, more preferably greater than or equal to 40 nm, still more preferably greater than or equal to 60 nm. When the thickness of the semiconductor layer 406a is made large, a distance from an interface between the adjacent insulator and the semiconductor layer 406a to the semiconductor layer 406b in which a channel is formed can be large. Since the productivity of the semiconductor device including the transistor 481 might be decreased, the semiconductor layer 406a has a region with a thickness, for example, less than or equal to 200 nm, preferably less than or equal to 120 nm, or further preferably less than or equal to 80 nm.

Silicon in the oxide semiconductor might serve as a carrier trap or a carrier generation source, for example. Therefore, the silicon concentration in the semiconductor layer 406b is preferably as low as possible. For example, a region with the silicon concentration of lower than 1×10¹⁹ atoms/cm³, preferably lower than 5×10¹⁸ atoms/cm³, or further preferably lower than 2×10¹⁸ atoms/cm³ which is measured by secondary ion mass spectrometry (SIMS) is provided between the semiconductor layer 406b and the semiconductor layer 406a. A region with the silicon concentration of lower than 1×10¹⁹ atoms/cm³, preferably lower than 5×10¹⁸ atoms/cm³, more preferably lower than 2×10¹⁸ atoms/cm³ which is measured by SIMS is provided between the semiconductor layer 406b and the semiconductor layer 406c.

The semiconductor layer 406b has a region in which the concentration of hydrogen which is measured by SIMS is lower than or equal to 2×102 θ atoms/cm³, preferably lower than or equal to 5×10¹⁹ atoms/cm³, further preferably lower than or equal to 1×10¹⁹ atoms/cm³, or still further preferably lower than or equal to 5×10¹⁸ atoms/cm³. It is preferable to reduce the concentration of hydrogen in the semiconductor layer 406a and the semiconductor layer 406c in order to reduce the concentration of hydrogen in the semiconductor layer 406b. The semiconductor layer 406a and the semiconductor layer 406c each have a region in which the concentration of hydrogen measured by SIMS is lower than or equal to 2×102 θ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. The semiconductor layer 406b has a region in which the concentration of nitrogen measured by SIMS is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³. It is preferable to reduce the concentration of nitrogen in the semiconductor layer 406a and the semiconductor layer 406c in order to reduce the concentration of nitrogen in the semiconductor layer 406b. The semiconductor layers 406a and 406c each have a region in which the concentration of nitrogen measured by SIMS is lower than 5×10¹⁹ atoms/cm³, preferably less than or equal to 5×10¹⁸ atoms/cm³, more preferably less than or equal to 1×10¹⁸ atoms/cm³, still more preferably less than or equal to 5×10¹⁷ atoms/cm³.

Note that when copper enters the oxide semiconductor, an electron trap might be generated. The electron trap might shift the threshold voltage of the transistor in the positive direction. Therefore, the concentration of copper on the surface of or in the semiconductor layer 406b is preferably as low as possible. For example, the semiconductor layer 406b preferably has a region in which the concentration of copper is lower than or equal to 1×10¹⁹ atoms/cm³, lower than or equal to 5×10¹⁸ atoms/cm³, or lower than or equal to 1×10¹⁸ atoms/cm³.

The above three-layer structure is an example. For example, a two-layer structure without the semiconductor layer 406a or the semiconductor layer 406c may be employed. A four-layer structure in which any one of the semiconductors described as examples of the semiconductor layer 406a, the semiconductor layer 406b, and the semiconductor layer 406c is provided below or over the semiconductor layer 406a or below or over the semiconductor layer 406c may be employed. An n-layer structure (n is an integer of 5 or more) in which any one of the semiconductors described as examples of the semiconductor layer 406a, the semiconductor layer 406b, and the semiconductor layer 406c is provided at two or more of the following positions: over the semiconductor layer 406a, below the semiconductor layer 406a, over the semiconductor layer 406c, and below the semiconductor layer 406c.

### <Formation Method of Inverter Circuit>

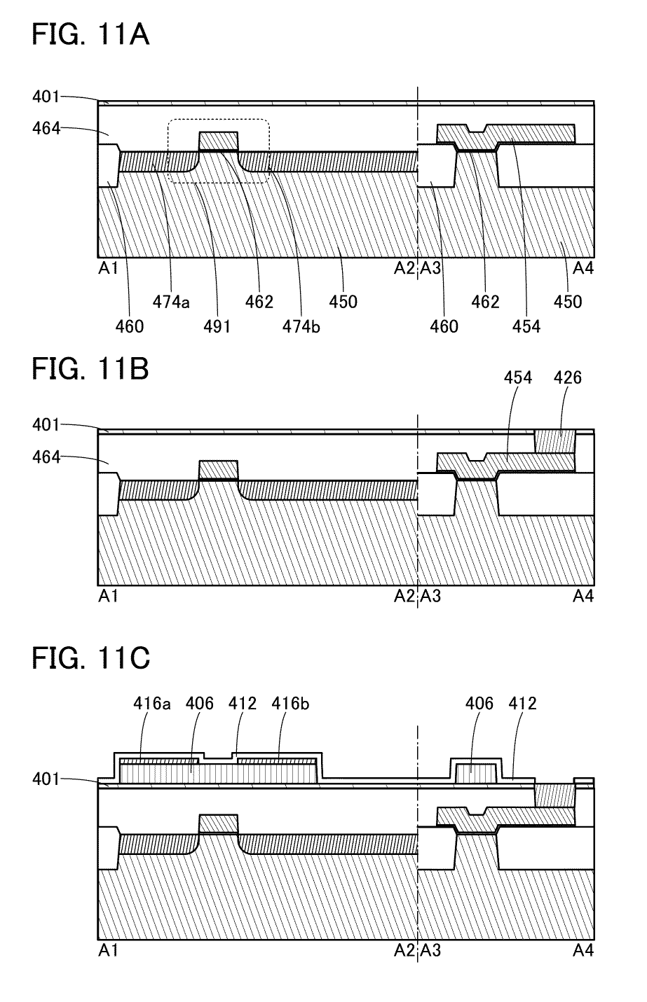

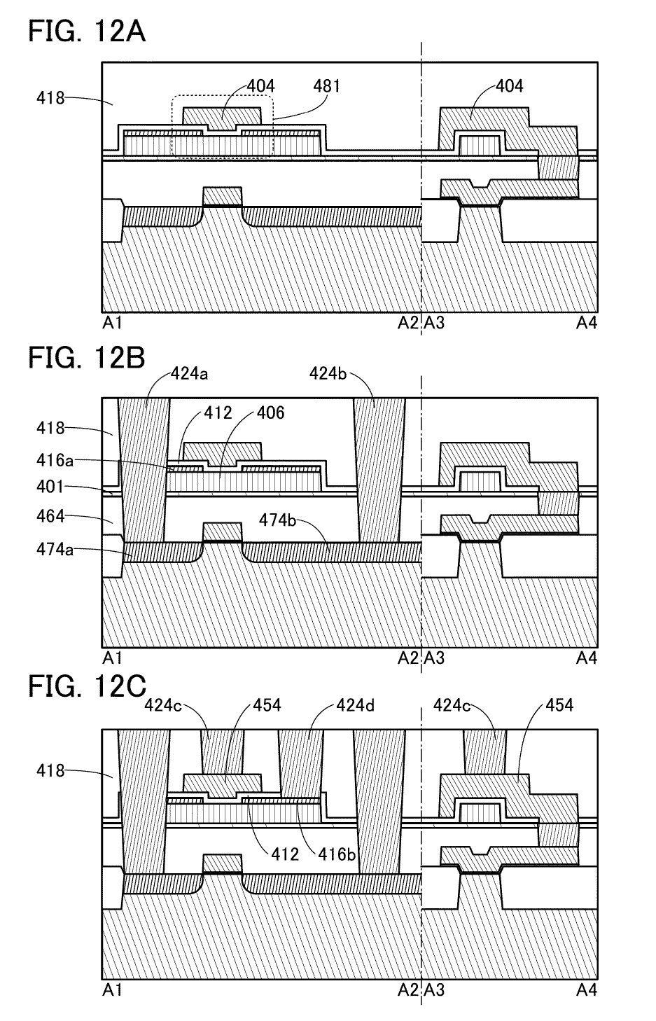

An example of a formation method of the inverter circuit in FIGS. 2A and 2B is described with reference to FIGS. 11A to 11C and FIGS. 12A to 12C.

FIGS. 11A to 11C and FIGS. 12A to 12C are cross-sectional views taken along dashed-dotted line A1-A2 and dashed-dotted line A3-A4 in FIG. 2A.

First, the semiconductor substrate 450 is prepared.

Next, an insulator to be the insulator 462 is deposited over the semiconductor substrate 450. The insulator to be the insulator 462 can be deposited by a sputtering method, a chemical vapor deposition (CVD) method, a molecular beam epitaxy (MBE) method, a pulsed laser deposition (PLD) method, an atomic layer deposition (ALD) method, a thermal oxidation method, a plasma oxidation method, or the like.

A CVD method includes a plasma enhanced CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas.

By using the PECVD method, a high-quality film can be formed at a relatively low temperature. The thermal CVD method, which does not use plasma, is a film formation method with less plasma damage to an object of the treatment. For example, a wiring, an electrode, an element (e.g., a transistor or a capacitor), and the like included in a semiconductor device may receive charges from plasma, and charge buildup may occur in some cases. In that case, because of the accumulated charges, the wiring, the electrode, the element, or the like in the semiconductor device may be broken. Such plasma damage is not caused in the case of using the thermal CVD method, and thus the yield of a semiconductor device can be increased. In addition, since plasma damage is not caused in the film formation by the thermal CVD method, a film with few defects can be obtained.

In addition, the ALD method is also a film formation method with less plasma damage to an object of the treatment. By using the ALD method, a film with few defects can be obtained since the plasma damage is not caused.

Different from a film formation method whereby particles released from a target are deposited, the CVD method and the ALD method are film formation methods whereby a film is formed by a reaction at a surface of an object of the treatment. Therefore, they are film formation methods whereby a film with favorable coverage is formed without being greatly affected by the shape of the object. In particular, a film formed by the ALD method has favorable coverage and excellent uniformity in thickness. Therefore, the ALD method is preferred for forming a film covering a surface of an opening portion with a high aspect ratio. However, film formation speed of the ALD method is relatively slow, and thus it may be preferable to use the ALD method in combination with another film formation method with high film formation speed such as the CVD method in some cases.

In the case of the CVD method or the ALD method, the composition of a film to be obtained can be controlled by adjusting the flow ratio of a source gas. For example, by the CVD method or the ALD method, a film with a desired composition can be formed by adjusting the flow ratio of a source gas. Moreover, with the CVD method or the ALD method, by changing the flow ratio of the source gases while forming the film, a film whose composition is continuously changed can be formed. In the case where the film is formed while changing the flow ratio of the source gases, as compared to the case where the film is formed using a plurality of deposition chambers, time taken for the film formation can be reduced because time taken for transfer and pressure adjustment is omitted. Thus, semiconductor devices can be manufactured with improved productivity.

Next, a protective insulator is deposited over the insulator to be the insulator 462 is formed. The protective insulator can be deposited by a sputtering method, a CVD method, an MBE method, a PLD method, an ALD method, or the like.

Next, the protective insulator, the insulator to be the insulator 462, and the semiconductor substrate 450 are partly processed by a photolithography method or the like. At this time, in the protective insulator, the insulator to be the insulator 462, and the semiconductor substrate 450, a groove is formed in a region where the insulator 460 is to be formed.

In the photolithography method, first, a resist is exposed to light through a photomask. Next, a region exposed to light is removed or left using a developing solution, so that a resist mask is formed. Then, etching through the resist mask is conducted. As a result, a conductor, a semiconductor, an insulator, or the like can be processed into a desired shape. The resist mask is formed by, for example, exposure of the resist to light using KrF excimer laser light, ArF excimer laser light, extreme ultraviolet (EUV) light, or the like. Alternatively, a liquid immersion technique may be employed in which a portion between a substrate and a projection lens is filled with liquid (e.g., water) to perform light exposure. An electron beam or an ion beam may be used instead of the above-mentioned light. Note that a photomask is not necessary in the case of using an electron beam or an ion beam. Note that dry etching treatment such as ashing and/or wet etching treatment can be used for removal of the resist mask.

Next, an insulator to be the insulator 460 is formed. The insulator to be the insulator 460 can be deposited by a sputtering method, a CVD method, an MBE method, a PLD method, an ALD method, or the like.

Then, an upper portion of the insulator to be the insulator 460 is removed so that the top surface of the insulator becomes parallel to a reference surface such as a rear surface of the semiconductor substrate 450. Such treatment is referred to as planarization treatment. As the planarization treatment, for example, chemical mechanical polishing (CMP) treatment, dry etching treatment, and the like are given. Here, the planarization treatment is performed until the protective insulator is exposed, whereby the insulator to be the insulator 460 can remain only in the groove formed in the protective insulator, the insulator to be the insulator 462, and the semiconductor substrate 450. In this manner, the insulator 460 can be formed.

Then, the protective insulator is removed.

Next, a conductor to be the conductor 454 is formed. The conductor to be the conductor 454 can be deposited by a sputtering method, a CVD method, an MBE method, a PLD method, an ALD method, or the like.

Then, the conductor to be the conductor 454 and the insulator to be the insulator 462 are processed by a photolithography method or the like to form the conductor 454 and the insulator 462.

Through the above process, the transistor 491 can be fabricated.

Next, the insulator 464 is deposited. The insulator 464 can be deposited by a sputtering method, a CVD method, an MBE method, a PLD method, an ALD method, or the like.

Then, the insulator 401 is deposited (see FIG. 11A). The insulator 401 can be deposited by a sputtering method, a CVD method, an MBE method, a PLD method, an ALD method, or the like.

Next, the insulator 401 and the insulator 464 are processed by a photolithography method or the like to form an opening portion that exposes the conductor 454.

Next, a conductor to be the conductor 426 is deposited. The conductor to be the conductor 426 can be deposited by a sputtering method, a CVD method, an MBE method, a PLD method, an ALD method, or the like. The conductor to be the conductor 426 is deposited so as to fill the opening portion formed in the insulator 401 and the insulator 464. Therefore, a CVD method (an MCVD method, in particular) is preferably used. A stacked-layer film of a conductor deposited by an ALD method or the like and a conductor deposited by a CVD method is preferred in some cases to increase adhesion of the conductor deposited by an MCVD method. For example, the stacked-layer film where titanium nitride and tungsten are deposited in this order may be used.

Then, planarization treatment is performed on the conductor to be the conductor 426. Here, the planarization treatment is performed until the insulator 401 is exposed, whereby the conductor to be the conductor 426 can remain only in the opening portion formed in the insulator 401 and the insulator 464. In this manner, the conductor 426 can be formed (see FIG. 11B).

Next, a semiconductor to be the semiconductor 406 is deposited. The semiconductor to be the semiconductor 406 can be deposited by a sputtering method, a CVD method, an MBE method, a PLD method, an ALD method, or the like. The semiconductor to be the semiconductor 406 is particularly preferably deposited by a sputtering method. At this time, as a target, a target having a single crystal structure is preferably used. The target having a single crystal structure includes a target having a polycrystalline structure. In this manner, the semiconductor 406 having high crystallinity, such as a CAAC-OS or an nc-OS, can be deposited.

Next, a conductor to be the conductor 416a and the conductor 416b is deposited. The conductor to be the conductor 416a and the conductor 416b can be deposited by a sputtering method, a CVD method, an MBE method, a PLD method, an ALD method, or the like.

Then, the conductor to be the conductor 416a and the conductor 416b is processed by a photolithography method or the like to form an island-shaped conductor.

Then, the semiconductor to be the semiconductor 406 is etched using the island-shaped conductor to form the island-shaped semiconductor 406.

Then, the island-shaped conductor is processed by a photolithography method to form the conductor 416a and the conductor 416b.

Next, an insulator to be the insulator 412 is deposited. The insulator to be the insulator 412 can be deposited by a sputtering method, a CVD method, an MBE method, a PLD method, an ALD method, or the like.

Then, the insulator to be the insulator 412 is processed by a photolithography method or the like to form an opening portion that exposes the conductor 426 (see FIG. 11C).

Next, a conductor to be the conductor 404 is deposited. The conductor to be the conductor 404 can be deposited by a sputtering method, a CVD method, an MBE method, a PLD method, an ALD method, or the like.

Then, the conductor to be the conductor 404 is processed by a photolithography method to form the conductor 404.

Through the above process, the transistor 481 can be fabricated.

Next, the insulator 418 is deposited (see FIG. 12A). The insulator 418 can be deposited by a sputtering method, a CVD method, an MBE method, a PLD method, an ALD method, or the like.

Then, the insulator 418, the insulator 412, the conductor 416a, the semiconductor 406, the insulator 401, and the insulator 464 are processed by a photolithography method or the like to form an opening portion that exposes the region 474a. Furthermore, the insulator 418, the insulator 412, the insulator 401, and the insulator 464 are processed by a photolithography method or the like to form an opening portion that exposes the region 474b. Note that these opening portions may be formed through different steps or the same step.

Next, a conductor to be the conductor 424a and the conductor 424b is deposited. The conductor to be the conductor 424a and the conductor 424b can be deposited by a sputtering method, a CVD method, an MBE method, a PLD method, an ALD method, or the like. The conductor to be the conductor 424a and the conductor 424b is deposited so as to fill the opening portion formed in the insulator 418, the insulator 412, the conductor 416a, the semiconductor 406, the insulator 401, and the insulator 464 and the opening portion formed in the insulator 418, the insulator 412, the insulator 401, and the insulator 464. Therefore, a CVD method (an MCVD method, in particular) is preferably used. A stacked-layer film of a conductor deposited by an ALD method or the like and a conductor deposited by a CVD method is preferred in some cases to increase adhesion of the conductor deposited by an MCVD method. For example, the stacked-layer film where titanium nitride and tungsten are deposited in this order may be used.

Then, planarization treatment is performed on the conductor to be the conductor 424a and the conductor 424b. Here, the planarization treatment is performed until the insulator 418 is exposed, whereby the conductor to be the conductor 424a and the conductor 424b can remain only in the opening portion formed in the insulator 418, the insulator 412, the conductor 416a, the semiconductor 406, the insulator 401, and the insulator 464 and the opening portion formed in the insulator 418, the insulator 412, the insulator 401, and the insulator 464. In this manner, the conductor 424a and the conductor 424b can be formed (see FIG. 12B). In the case where these opening portions are formed through different steps, a conductor to be the conductor 424a and a conductor to be the conductor 424b may be formed through different steps.

Then, the insulator 418 is processed by a photolithography method or the like to form an opening portion that exposes the conductor 454. Furthermore, the insulator 418 and the insulator 412 are processed by a photolithography method or the like to form an opening portion that exposes the conductor 416b. Note that these opening portions may be formed through different steps or the same step.

Next, a conductor to be the conductor 424c and the conductor 424d is deposited. The conductor to be the conductor 424c and the conductor 424d can be deposited by a sputtering method, a CVD method, an MBE method, a PLD method, an ALD method, or the like. The conductor to be the conductor 424c and the conductor 424d is deposited so as to fill the opening portion formed in the insulator 418 and the opening portion formed in the insulator 418 and the insulator 412. Therefore, a CVD method (an MCVD method, in particular) is preferably used. A stacked-layer film of a conductor deposited by an ALD method or the like and a conductor deposited by a CVD method is preferred in some cases to increase adhesion of the conductor deposited by an MCVD method. For example, the stacked-layer film where titanium nitride and tungsten deposited formed in this order may be used.

Then, planarization treatment is performed on the conductor to be the conductor 424c and the conductor 424d. Here, the planarization treatment is performed until the insulator 418 is exposed, whereby the conductor to be the conductor 424c and the conductor 424d can remain only in the opening portion formed in the insulator 418 and the opening portion formed in the insulator 418 and the insulator 412. In this manner, the conductor 424c and the conductor 424d can be formed (see FIG. 12C). In the case where these opening portions are formed through different steps, a conductor to be the conductor 424c and a conductor to be the conductor 424d may be formed through different steps.

Note that the order of steps described with reference to FIG. 12B and FIG. 12C may be reversed.

In this manner, the inverter circuit in FIGS. 2A and 2B can be formed.

### <Analog Switch Circuit>

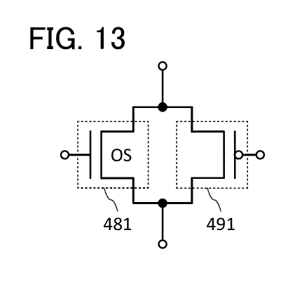

A circuit diagram in FIG. 13 shows a configuration of a so-called analog switch circuit in which the source and the drain of the p-channel transistor 491 are connected to the source and the drain of the n-channel transistor 481. An analog switch circuit can be used as a logic circuit included in a semiconductor device or a part of the logic circuit. Note that, as the transistor 491, an n-channel transistor may be used. Furthermore, as the transistor 481, a p-channel transistor may be used.

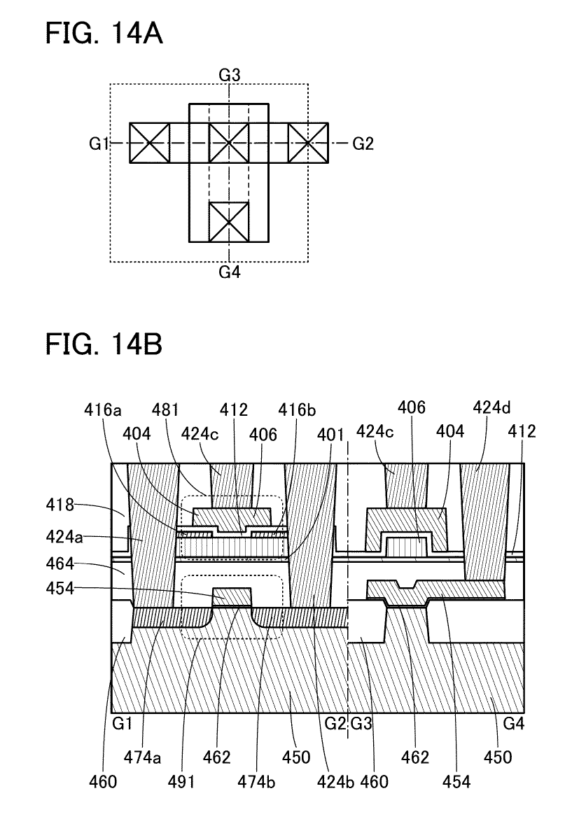

FIG. 14A is a top view of the analog switch circuit corresponding to FIG. 13. FIG. 14B is a cross-sectional view taken along dashed-dotted line G1-G2 and dashed-dotted line G3-G4 in FIG. 14A.

The analog switch circuit in FIGS. 14A and 14B is different from the inverter circuit in FIGS. 2A and 2B in the positions at which the transistor 481 and the transistor 491 are electrically connected to each other. Thus, the area of the whole semiconductor device can be reduced as in the inverter circuit in FIGS. 2A and 2B and the like.

The analog switch circuit in FIG. 14B includes the insulator 464, the insulator 401, the insulator 418, the conductor 424a, the conductor 424b, the conductor 424c, and the conductor 424d.

The insulator 464 is placed over the transistor 491. The insulator 401 is placed over the insulator 464. The transistor 481 is placed over the insulator 401. The insulator 418 is placed over the transistor 481.

An opening portion reaching the region 474a is provided in the insulator 418, the insulator 412, the conductor 416a, the semiconductor 406, the insulator 401, and the insulator 464. The conductor 424a is embedded in the opening portion. An opening portion reaching the region 474b is provided in the insulator 418, the insulator 412, the conductor 416b, the semiconductor 406, the insulator 401, and the insulator 464. The conductor 424b is embedded in the opening portion. An opening portion reaching the conductor 404 is provided in the insulator 418. The conductor 424c is embedded in the opening portion. An opening portion reaching the conductor 454 is provided in the insulator 418, the insulator 412, the insulator 401, and the insulator 464. The conductor 424d is embedded in the opening portion.

Thus, the transistor 491 is electrically connected to the transistor 481 through the conductor provided in the opening portion. Specifically, the region 474a of the transistor 491 is electrically connected to the conductor 416a of the transistor 481 through the conductor 424a. The region 474b of the transistor 491 is electrically connected to the conductor 416b of the transistor 481 through the conductor 424b. The conductor 424a and the conductor 424b reach the transistor 491 by passing through the transistor 481 and the like; thus, the conductor 424a and the conductor 424b each can be referred to as a through electrode. When the through electrode is included, the transistor 491 and the transistor 481 can overlap each other; thus, the area occupied by the analog switch circuit can be reduced. Thus, the integration degree of the semiconductor device including the analog switch circuit can be increased.

Note that, for the other structures, refer to the descriptions of the inverter circuit in FIGS. 2A and 2B, FIGS. 3A and 3B, FIGS. 4A and 4B, FIGS. 5A and 5B, FIGS. 6A and 6B, FIGS. 7A and 7B, FIGS. 8A and 8B, FIGS. 9A and 9B, FIGS. 10A and 10B, FIGS. 11A to 11C, and FIGS. 12A to 12C.

As described in the description of the inverter circuit, the analog switch circuit of one embodiment of the present invention can also have a variety of structures. The structure described above is an example. Thus, a novel analog switch circuit can be formed by combining a part of one structure and a part of another structure. For example, with a part of the structure of the inverter circuit, a novel analog switch circuit can be formed.

Furthermore, the formation method of the inverter circuit can be referred to for the formation method of the analog switch circuit.

### <NAND Circuit>

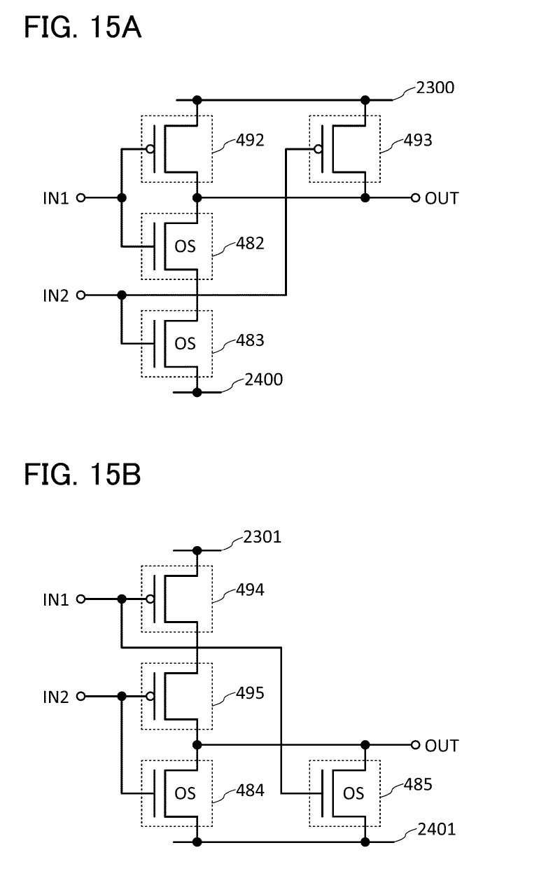

A circuit diagram in FIG. 15A shows a p-channel transistor 492, a p-channel transistor 493, an n-channel transistor 482, an n-channel transistor 483, a wiring 2300, a wiring 2400, a terminal IN1, a terminal IN2, and a terminal OUT. Note that, through the wiring 2300, a higher potential than the potential supplied through the wiring 2400 can be supplied.

A gate of the transistor 492 is electrically connected to the terminal Ni. One of a source and a drain of the transistor 492 is electrically connected to the wiring 2300. The other of the source and the drain of the transistor 492 is electrically connected to the terminal OUT.

A gate of the transistor 482 is electrically connected to the terminal Ni. One of a source and a drain of the transistor 482 is electrically connected to the terminal OUT.

A gate of the transistor 493 is electrically connected to the terminal IN2. One of a source and a drain of the transistor 493 is electrically connected to the wiring 2300. The other of the source and the drain of the transistor 493 is electrically connected to the terminal OUT.

A gate of the transistor 483 is electrically connected to the terminal IN2. One of a source and a drain of the transistor 483 is electrically connected to the other of the source and the drain of the transistor 482. The other of the source and the drain of the transistor 483 is electrically connected to the wiring 2400.

Thus, the circuit diagram in FIG. 15A shows a configuration of a so-called NAND circuit. A NAND circuit can be used as a logic circuit included in a semiconductor device or a part of the logic circuit.

In the NAND circuit in FIG. 15A, as an inverter circuit including the transistor 492 and the transistor 482, any of the above-described inverter circuits can be used, for example. As the transistor 493, the above-described transistor 491 can be used. As the transistor 483, the above-described transistor 481 can be used.

### <NOR Circuit>

A circuit diagram in FIG. 15B includes a p-channel transistor 494, a p-channel transistor 495, an n-channel transistor 484, an n-channel transistor 485, a wiring 2301, a wiring 2401, the terminal Ni, the terminal IN2, and the terminal OUT. Note that, through the wiring 2301, a higher potential than the potential supplied through the wiring 2401 can be supplied.

A gate of the transistor 494 is electrically connected to the terminal IN1. One of a source and a drain of the transistor 494 is electrically connected to the wiring 2301.

A gate of the transistor 495 is electrically connected to the terminal IN2. One of a source and a drain of the transistor 495 is electrically connected to the other of the source and the drain of the transistor 494. The other of the source and the drain of the transistor 495 is electrically connected to the terminal OUT.

A gate of the transistor 484 is electrically connected to the terminal IN2. One of a source and a drain of the transistor 484 is electrically connected to the terminal OUT. The other of the source and the drain of the transistor 484 is electrically connected to the wiring 2401.

A gate of the transistor 485 is electrically connected to the terminal Ni. One of a source and a drain of the transistor 485 is electrically connected to the terminal

OUT. The other of the source and the drain of the transistor 485 is electrically connected to the wiring 2401.

Thus, the circuit diagram in FIG. 15B shows a configuration of a so-called NOR circuit. A NOR circuit can be used as a logic circuit included in a semiconductor device or a part of the logic circuit.

In the NOR circuit in FIG. 15B, as an inverter circuit including the transistor 495 and the transistor 484, any of the above-described inverter circuits can be used, for example. As the transistor 494, the above-described transistor 491 can be used. As the transistor 485, the above-described transistor 481 can be used.

In each of the logic circuits described with reference to FIGS. 2A and 2B, FIGS. 3A and 3B, FIGS. 4A and 4B, FIGS. 5A and 5B, FIGS. 6A and 6B, FIGS. 7A and 7B, FIGS. 8A and 8B, FIGS. 9A and 9B, FIGS. 10A and 10B, FIGS. 11A to 11C, FIGS. 12A to 12C, FIG. 13, FIGS. 14A and 14B, FIGS. 15A and 15B, and the like, a p-channel transistor is formed utilizing a semiconductor substrate, and an n-channel transistor is formed above that; therefore, an occupation area of the element can be reduced. That is, the integration degree of the semiconductor device including any of these logic circuits can be improved. In addition, the manufacturing process can be simplified compared to the case where an n-channel transistor and a p-channel transistor are formed utilizing the same semiconductor substrate; therefore, the productivity of the semiconductor device can be increased. Moreover, the yield of the semiconductor device can be improved. For the p-channel transistor, some complicated steps such as formation of lightly doped drain (LDD) regions, formation of a shallow trench structure, or distortion design can be omitted in some cases. Therefore, the productivity and the yield of these semiconductor devices can be increased in some cases, compared with those of a semiconductor device where an n-channel transistor is formed utilizing the semiconductor substrate.

### <CPU>

A CPU including any of the above-described transistors or the above-described logic circuits is described below.

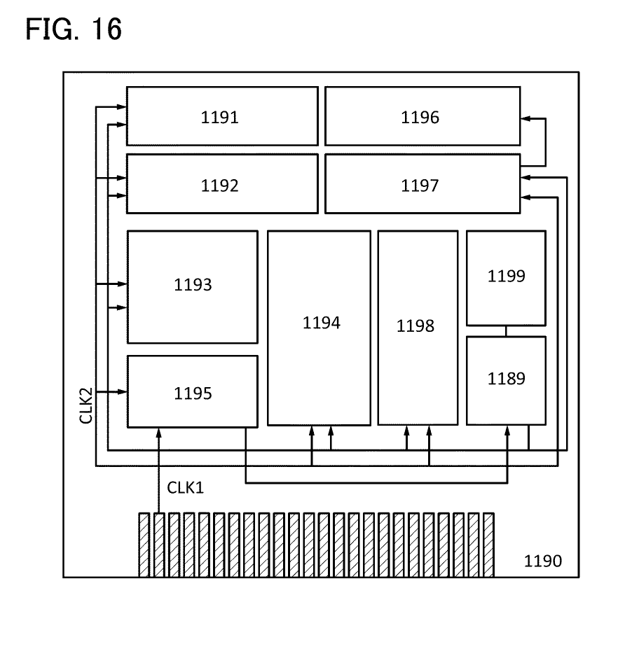

FIG. 16 is a block diagram illustrating a configuration example of a CPU including any of the above-described transistors as a component.

The CPU illustrated in FIG. 16 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198, a rewritable ROM 1199, and an ROM interface 1189. A semiconductor substrate, an SOI substrate, a glass substrate, or the like is used as the substrate 1190. The ROM 1199 and the ROM interface 1189 may be provided over a separate chip. Needless to say, the CPU in FIG. 16 is just an example of a simplified structure, and an actual CPU may have a variety of structures depending on the application. For example, the CPU may have the following configuration: a structure including the CPU illustrated in FIG. 16 or an arithmetic circuit is considered as one core; a plurality of the cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 processes an interrupt request from an external input/output device or a peripheral circuit depending on its priority or a mask state. The register controller 1197 generates an address of the register 1196, and reads/writes data from/to the register 1196 depending on the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 on the basis of a reference clock signal CLK1, and supplies the internal clock signal CLK2 to the above circuits.

In the CPU illustrated in FIG. 16, a memory cell is provided in the register 1196. For the memory cell of the register 1196, any of the above-described transistors, the above-described logic circuits, or the like can be used.

In the CPU illustrated in FIG. 16, the register controller 1197 selects operation of retaining data in the register 1196 in accordance with an instruction from the ALU 1191. That is, the register controller 1197 selects whether data is held by a flip-flop or by a capacitor in the memory cell included in the register 1196. When data holding by the flip-flop is selected, a power supply voltage is supplied to the memory cell in the register 1196. When data holding by the capacitor is selected, the data is rewritten in the capacitor, and supply of the power supply voltage to the memory cell in the register 1196 can be stopped.

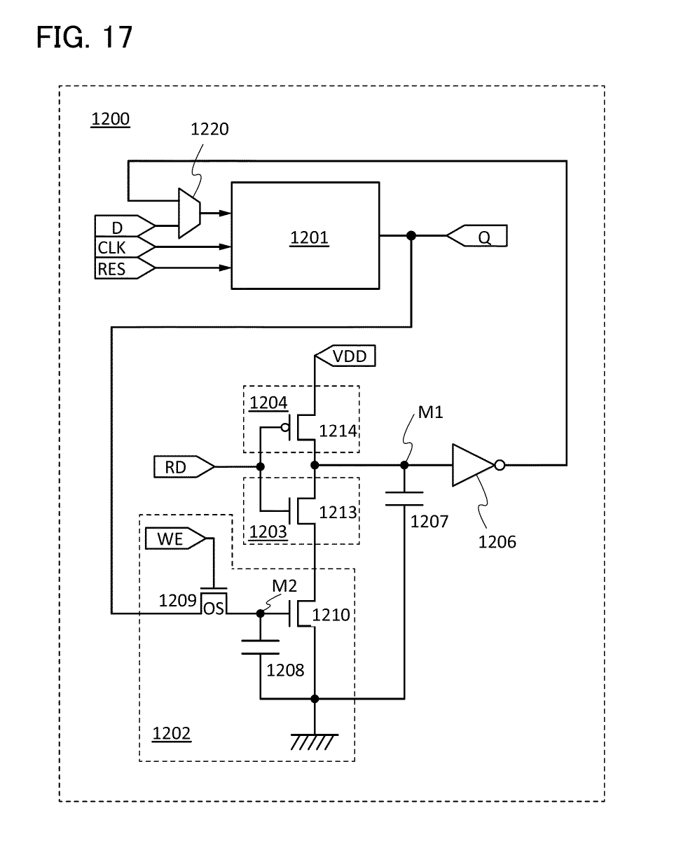

FIG. 17 is an example of a circuit diagram of a memory element 1200 that can be used as the register 1196. A memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described logic circuit or the like can be used as the circuit 1202. When supply of a power supply voltage to the memory element 1200 is stopped, GND (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with a low power supply potential (e.g.,

GND) or a high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the line, or the like is actively utilized.

A control signal WE is input to the gate of the transistor 1209. As for each of the switch 1203 and the switch 1204, a conduction state or a non-conduction state between the first terminal and the second terminal is selected by the control signal RD which is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 17 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 17, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 17, the transistors included in the memory element 1200 except for the transistor 1209 can each be a transistor in which a channel is formed in a film formed using a semiconductor other than an oxide semiconductor or in the substrate 1190. For example, the transistor can be a transistor whose channel is formed in a silicon film or a silicon substrate. Alternatively, all the transistors in the memory element 1200 may be a transistor in which a channel is formed in an oxide semiconductor. Further alternatively, in the memory element 1200, a transistor in which a channel is formed in an oxide semiconductor can be included besides the transistor 1209, and a transistor in which a channel is formed in a layer or the substrate 1190 including a semiconductor other than an oxide semiconductor can be used for the rest of the transistors.

As the circuit 1201 in FIG. 17, for example, a flip-flop circuit can be used. As the logic element 1206, for example, an inverter or a clocked inverter can be used.

In a period during which the memory element 1200 is not supplied with the power supply voltage, data stored in the circuit 1201 can be retained by the capacitor 1208 which is provided in the circuit 1202.

The off-state current of a transistor in which a channel is formed in an oxide semiconductor is extremely low. For example, the off-state current of a transistor in which a channel is formed in an oxide semiconductor is significantly lower than that of a transistor in which a channel is formed in silicon having crystallinity. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the above-described memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 varies to some degree.

By using the above-described memory element 1200 for a memory device such as a register or a cache memory included in a processor, data in the memory device can be prevented from being lost owing to the stop of the supply of the power supply voltage. Further, shortly after the supply of the power supply voltage is restarted, the memory element can be returned to the same state as that before the power supply is stopped. Therefore, the power supply can be stopped even for a short time in the processor or one or a plurality of logic circuits included in the processor. Accordingly, power consumption can be suppressed.

Although the memory element 1200 is used in a CPU as an example, the memory element 1200 can also be used in an LSI such as a digital signal processor (DSP), a custom LSI, or a programmable logic device (PLD), and a radio frequency identification (RF-ID).

### <Electronic Device>

The semiconductor device of one embodiment of the present invention can be used for display devices, personal computers, image reproducing devices provided with recording media (typically, devices which reproduce the content of recording media such as digital versatile discs (DVDs) and have displays for displaying the reproduced images), or the like. Other examples of electronic devices that can be equipped with the semiconductor device of one embodiment of the present invention are mobile phones, game machines including portable game consoles, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 18A to 18F illustrate specific examples of these electronic devices.

FIG. 18A illustrates a portable game console including a housing 901, a housing 902, a display portion 903, a display portion 904, a microphone 905, a speaker 906, an operation key 907, a stylus 908, and the like. Although the portable game machine in FIG. 18A has the two display portions 903 and 904, the number of display portions included in a portable game console is not limited to this.

FIG. 18B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched depending on the angle between the first housing 911 and the second housing 912 at the joint 915. A display device with a position input function may be used as at least one of the first display portion 913 and the second display portion 914. Note that the position input function can be added by provision of a touch panel in a display device. Alternatively, the position input function can be added by provision of a photoelectric conversion element called a photosensor in a pixel portion of a display device.

FIG. 18C illustrates a laptop personal computer, which includes a housing 921, a display portion 922, a keyboard 923, a pointing device 924, and the like.

FIG. 18D illustrates an electric refrigerator-freezer including a housing 931, a door for a refrigerator 932, a door for a freezer 933, and the like.

FIG. 18E illustrates a video camera, which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and the angle between the first housing 941 and the second housing 942 can be changed with the joint 946. An image displayed on the display portion 943 may be switched in accordance with the angle at the joint 946 between the first housing 941 and the second housing 942.

FIG. 18F illustrates an ordinary vehicle including a car body 951, wheels 952, a dashboard 953, lights 954, and the like.

### REFERENCE NUMERALS

401: insulator, 402: insulator, 404: conductor, 406: semiconductor, 406a: semiconductor layer, 406b: semiconductor layer, 406c: semiconductor layer, 412: insulator, 416a: conductor, 416b: conductor, 418: insulator, 424a: conductor, 424b: conductor, 424c: conductor, 424d: conductor, 426: conductor, 450: semiconductor substrate, 452: insulator, 454: conductor, 460: insulator, 461: insulator, 462: insulator, 464: insulator, 474a: region, 474b: region, 481: transistor, 482: transistor, 483: transistor, 484: transistor, 485: transistor, 491: transistor, 492: transistor, 493: transistor, 494: transistor, 495: transistor, 901: housing, 902: housing, 903: display portion, 904: display portion, 905: microphone, 906: speaker, 907: operation key, 908: stylus, 911: housing, 912: housing, 913: display portion, 914: display portion, 915: joint, 916: operation key, 921: housing, 922: display portion, 923: keyboard, 924: pointing device, 931: housing, 932:

refrigerator, 933: freezer, 941: housing, 942: housing, 943: display portion, 944: operation key, 945: lens, 946: joint, 951: car body, 952: wheels, 953: dashboard, 954: lights, 1189: ROM interface, 1190: substrate, 1191: ALU, 1192: ALU controller, 1193: instruction decoder, 1194: interrupt controller, 1195: timing controller, 1196: register, 1197: register controller, 1198: bus interface, 1199: ROM, 1200: memory element, 1201: circuit, 1202: circuit, 1203: switch, 1204: switch, 1206: logic element, 1207: capacitor, 1208: capacitor, 1209: transistor, 1210: transistor, 1213: transistor, 1214: transistor, 1220: circuit, 2300: wiring, 2301: wiring, 2400: wiring, 2401: wiring, 5120: substrate, 5161: region.

This application is based on Japanese Patent Application serial no. 2014-081822 filed with Japan Patent Office on Apr. 11, 2014, the entire contents of which are hereby incorporated by reference.

1. A semiconductor device comprising:
a first semiconductor;
a second semiconductor;
a first conductor;
a second conductor;
a third conductor;
a fourth conductor;
a first insulator; and
a second insulator,
wherein a first region of the first semiconductor and a first region of the second semiconductor overlap each other,
wherein a first region of the first conductor and the first region of the first semiconductor overlap each other with the first insulator interposed therebetween,
wherein a first region of the second conductor and the first region of the second semiconductor overlap each other with the second insulator interposed therebetween,
wherein a first region of the third conductor is in contact with a second region of the first semiconductor,
wherein a second region of the third conductor is in contact with a second region of the second semiconductor,
wherein a first region of the fourth conductor is in contact with a second region of the first conductor, and
wherein a second region of the fourth conductor is in contact with a second region of the second conductor.

2. The semiconductor device according to claim 1,
wherein the first semiconductor comprises single crystal silicon.

3. The semiconductor device according to claim 1,
wherein the second semiconductor comprises indium oxide.

4. An electronic device comprising:
the semiconductor device according to claim 1; and
any one of a display device, a microphone, and a speaker.

5. A semiconductor device comprising:
a first semiconductor;
a second semiconductor;
a first conductor;
a second conductor;
a third conductor;
a fourth conductor;
a first insulator; and
a second insulator,
wherein a first region of the first semiconductor and a first region of the second semiconductor overlap each other,
wherein a first region of the first conductor and the first region of the first semiconductor overlap each other with the first insulator interposed therebetween,
wherein a first region of the second conductor and the first region of the second semiconductor overlap each other with the second insulator interposed therebetween,
wherein a first region of the third conductor is in contact with a second region of the first semiconductor,
wherein a second region of the third conductor is in contact with a second region of the second semiconductor,
wherein a first region of the fourth conductor is in contact with a third region of the first semiconductor, and
wherein a second region of the fourth conductor is in contact with a third region of the second semiconductor.

6. The semiconductor device according to claim 5,
wherein the first semiconductor comprises single crystal silicon.

7. The semiconductor device according to claim 5,
wherein the second semiconductor comprises indium oxide.

8. An electronic device comprising:
the semiconductor device according to claim 5; and
any one of a display device, a microphone, and a speaker.
